(19) United States
(12) Patent Application Publication
(10) Pub. No.: US 2024/0341055 A1
(43) Pub. Date: Oct. 10, 2024

(54) DUCT MODULE AND POWER CONVERSION MODULE COMPRISING SAME

(71) Applicant: LS ELECTRIC CO., LTD., Anyang-si, Gyeonggi-do (KR)

(72) Inventors: Jeong Woo LIM, Anyang-si, Gyeonggi-do (KR); Jung Wook SIM, Anyang-si, Gyeonggi-do (KR)

(21) Appl. No.: 18/292,215

(22) PCT Filed: Oct. 17, 2022
(86) PCT No.: PCT/KR2022/015773

§ 371 Date: Jan. 25, 2024

(30) Foreign Application Priority Data
Dec. 22, 2021 (KR) 10-2021-0185356

(51) Int. Cl. H05K 7/20

(52) U.S. Cl. CPC H05K 7/20145; H05K 7/20909

(57) ABSTRACT

A duct module and a power conversion module including the same are disclosed. The duct module according to an aspect of the present disclosure may include: a duct body formed to extend in one direction and communicating with a flow path member respectively; and a flow path coupling part coupling the duct body to the flow path member respectively and, wherein the duct body includes a duct space that is formed inside the duct body, extends in the one direction, and is formed to be open at each end in the extending direction to communicate with the flow path member; and at least one surface surrounding the duct space in an outer circumferential direction.

### FIELD

The present disclosure relates to a duct module and a power conversion module including the same, and more particularly, to a duct module having improved insulation performance and cooling efficiency and a power conversion module including the same.

### BACKGROUND

The transformer is commonly referred to a device that converts the value of an alternating voltage or alternating current using electromagnetic induction. The power generated by the power plant is transferred in a boosted state to minimize power losses. When the power is transferred to the load in the above state, there is a risk of loss of equipment and safety accidents, and thus the transferred power is generally dropped and transferred to the load.

The conventional type of transformer is provided as a single device having a fixed transforming capacity. That is, it is general that the transformer installed at a specific position is configured to transform only a predetermined size of power and supply it to the load. It is difficult for the transformer as described above to actively respond to future changes in power demand and supply form.

Recently, a modular semiconductor transformer that improves the disadvantages of the conventional type of transformer is actively developed. The modular semiconductor transformer includes a plurality of voltage-transforming modules that are formed to have a predetermined voltage-transforming capacity and are electrically connected to each other. The voltage-transforming capacity of the modular semiconductor transformer can be easily changed by adjusting the number of the plurality of voltage-transforming modules.

Meanwhile, in the case of the modular semiconductor transformer, isolation and cooling of the plurality of voltage-transforming modules stand out as important factors. That is, in the case of the conventional type of transformer, the arrangement for cooling and insulating the components can be performed at the design stage, and thus the insulation and cooling between the components of the transformer are not a big problem.

On the other hand, in the case of the modular semiconductor transformer, it is difficult to determine the number and arrangement method of the voltage-transforming modules to be installed during operation at the design stage. Therefore, there is a need for a method for insulating and cooling between the plurality of voltage-transforming modules constituting the modular semiconductor transformer.

Furthermore, the voltage-transforming modules are generally formed in a miniaturized size to maximize the advantages of space. Therefore, the cooling of the voltage-transforming module itself and the insulation between the components of the voltage-transforming module are also important factors.

By the way, as is known, miniaturization of size has a trade-off relationship with cooling and insulating efficiency. Therefore, techniques for achieving the cooling and insulation of the components while modularizing electric devices have been introduced.

Korean Patent Registration No. 10-1545187 discloses packaging of a power source using modular electronic modules. Specifically, a configuration is disclosed that provides a transformer compartment and a power cell compartment in a vertical configuration so that air for cooling can flow through parallel linear paths.

The packaging of the power source using the modular electronic modules disclosed by the above prior document only provides a method for cooling between the modules. In other words, the above prior document does not provide a method for effectively cooling the components constituting each module itself.

Korean Patent Laid-Open No. 10-2013-0049739 discloses a power semiconductor module cooling device. Specifically, the power semiconductor module cooling device is disclosed that can prevent leakage of cooling fluid for cooling a power semiconductor and suppress a decrease in cooling efficiency.

However, the prior document assumes that a separate cooling device is provided. In other words, the power semiconductor module cooling device disclosed in the above prior document is operated by being coupled to the power semiconductor module, and does not provide a method for flowing the refrigerant in the power semiconductor module itself.

Furthermore, the above prior documents do not disclose a consideration of technical tasks for maintaining insulating between the components constituting each module and miniaturizing each module.
(Patent Document 1) Korean Patent Registration No. 10-1545187 (2015.08.18.)
(Patent Document 2) Korean Patent Laid-Open No. 10-2013-0049739 (2013.05.14.)

### SUMMARY

### Technical Problem

The present disclosure is intended to solve the above problems, and it is an object of the present disclosure to provide a duct module having a structure in which a fluid flow path for cooling components can be easily formed, and a power conversion module including the same.

Another object of the present disclosure is to provide a duct module having a structure in which cooling efficiency of components can be improved, and a power conversion module including the same.

Still another object of the present disclosure is to provide a duct module having a structure in which a size can be miniaturized, and a power conversion module including the same.

Still another object of the present disclosure is to provide a duct module having a structure in which insulating between components can be ensured, and a power conversion module including the same.

Still another object of the present disclosure is to provide a duct module having a structure in which manufacturing is easy, and a power conversion module including the same.

The technical problems of the present disclosure are not limited to the above-mentioned technical problems, and other technical problems not mentioned will be clearly understood by those skilled in the art to which the present disclosure pertains from the following description.

### Technical Solution

According to an aspect of the present disclosure, there may be provided a duct module including a duct body formed to extend in one direction and communicating with a flow path member respectively; and a flow path coupling part coupling the duct body to the flow path member respectively and, wherein the duct body includes a duct space that is formed inside the duct body, extends in the one direction, and is formed to be open at each end in the extending direction to communicate with the flow path member; and at least one surface surrounding the duct space in an outer circumferential direction.

In this case, a duct module may be provided, wherein the duct body includes a protrusion formed to extend toward the duct space on the at least one surface, and in contact with an end surface in the extending direction of the flow path member.

In addition, a duct module may be provided, wherein the duct body comprises: a pair of surfaces continuous with each other at a predetermined angle to partially surround the duct space, and wherein the protrusion protrudes from any one surface of the pair of surfaces and is disposed adjacent to the other surface of the pair of surfaces.

In this case, a duct module may be provided, wherein the duct body includes a first surface that surrounds one side of the duct space; a second surface that is disposed to face the first surface with the duct space interposed therebetween, and surrounds another side of the duct space; a third surface that is continuous with the first surface and the second surface, respectively, and surrounds still another side of the duct space; and a fourth surface that is continuous with the first surface and the second surface, respectively, and is disposed to face the third surface with the duct space interposed therebetween, and surrounds the other side of the duct space, wherein the first surface, the second surface, the third surface, and the fourth surface extend in the one direction.

In addition, a duct module may be provided, wherein the duct body includes a first protrusion protruding on any one surface of the first surface to the fourth surface toward the duct space; and a second protrusion protruding on the other surface of the first surface to the fourth surface toward the duct space, wherein the first protrusion and the second protrusion contact with a surface of one end facing the duct body among the both ends in the extending direction of the flow path member.

In this case, a duct module may be provided, wherein the first protrusion and the second protrusion are disposed to be spaced apart from each other in a diagonal direction of the duct space.

In addition, a duct module may be provided, wherein the first protrusion is disposed adjacent to one surface continuous with the one surface at a predetermined angle, and the second protrusion is disposed adjacent to the other surface continuous with the other surface at a predetermined angle.

In this case, a duct module may be provided, wherein the flow path member extends along the one direction, and the flow path coupling part extends in the one direction to surround an outer circumference of one end facing the flow path member among both ends in the extending direction of the duct body; and an outer circumference of one end facing the duct body among both ends in the extending direction of the flow path member.

In addition, a duct module may be provided, wherein the duct body and the flow path coupling part are formed of an electric insulating material.

In this case, a duct module may be provided, wherein one end of the direction in which the duct body extends is coupled to a first flow path member of the outside to which power of a voltage of a predetermined magnitude is electrically connected, the other end of the direction in which the duct body extends is coupled to a second flow path member of the outside to which power of a voltage of a different magnitude from the predetermined magnitude is electrically connected, and the distance between the one end and the other end is proportional to the difference in magnitude between the voltage of the predetermined magnitude electrically connected to the first flow path member and the voltage of the different magnitude electrically connected to the second flow path member.

According to other aspect of the present disclosure, there may be provided a power conversion module including a housing having an accommodating space therein and communicating with the outside; an electrically connected part that is accommodated in the accommodating space, is electrically connected to an external power source and an external load, respectively, receives power from the external power source, and transforms the received power and transmits the transformed power to the external load; a flow path part that is accommodated in the accommodating space, is located adjacent to the electrically connected part, and in which a flow path space communicating with the outside is formed, and through which a fluid heat-exchanging with the electrically connected part flows; and a duct module that is accommodated in the accommodating space, and in which a duct space communicating with the flow path space is formed, and that forms a passage with the flow path part, wherein the fluid flows through the passage, and wherein the flow path part and the duct module are formed to extend in one direction, and the fluid flows along the one direction inside the flow path part and inside the duct module.

In this case, a power conversion module may be provided, wherein the flow path part includes a plurality of partition members located in the flow path space and formed in a plate shape extended along the one direction, and the flow path space is divided into a plurality of spaces by the plurality of the partition members, and the fluid introduced is branched and flows in each of the plurality of spaces.

In addition, a power conversion module may be provided, wherein the introduced fluid flows in the flow path space and the duct space in order, and the branched fluid flowing in the plurality of spaces is mixed in the duct space.

In this case, a power conversion module may be provided, wherein the duct module includes a duct body with the duct space formed therein; and a flow path coupling part surrounding an outer circumference of the duct body and extending toward the flow path part from an end of the duct body in the extending direction.

In addition, a power conversion module may be provided, wherein the duct module comprises a protrusion formed to extend toward the duct space on a surface surrounding the duct space, and the flow path part is disposed so that a surface of one end in extending direction thereof is in contact with the protrusion.

In this case, a power conversion module may be provided, wherein the flow path coupling part surrounds each end of the duct body and the flow path part facing each other from the outside.

### Advantageous Effects

According to the above configuration, the duct module and the power conversion module including the same according to the embodiment of the present disclosure can simplify the flow path of the fluid for cooling the components.

First, the duct module is formed to extend in one direction. The duct module is coupled to and communicates with the flow path part extending in the one direction. The flow path part communicates with the outside so that a fluid for cooling can be introduced. The introduced fluid passes through the flow path and the duct module in order and can heat-exchange with any member.

Therefore, the fluid flowing inside the flow path part and the duct module flows along the flow path extending along the extending direction of the flow path and the duct module, that is, the one direction. Accordingly, the introduced fluid can be formed simplified along the one direction.

In addition, according to the above configuration, the duct module and the power conversion module including the same according to the embodiment of the present disclosure can improve the cooling efficiency of the components.

To begin with, as described above, the fluid flowing into the flow path part and the duct module flows along the one direction. Accordingly, the flow rate of the fluid can be increased, thereby increasing the amount of fluid passing and the amount of heat-exchanged during the same time.

On the other hand, a partition member is provided in the flow path part. The partition member divides the space inside the flow path part into a plurality of small spaces. The introduced fluid branches into a plurality of small spaces and can flow while absorbing different amounts of heat. The fluid introduced into the duct module is mixed and heat-exchanged to each other to be adjusted to a thermal equilibrium state.

The fluid passing through the duct module flows toward the other flow path. In this case, since the fluid introduced into the other flow path is adjusted to a state of thermal equilibrium, heat-exchange efficiency inside the other flow path may be improved.

Therefore, the fluid can pass through the flow path part and duct module while maintaining at a constant heat-exchange efficiency. Accordingly, the cooling efficiency of the power conversion module can be improved.

In addition, according to the above configuration, the duct module and the power conversion module including the same according to the embodiment of the present disclosure can be miniaturized in size.

As described above, the flow path part and the duct module are disposed side by side along one direction. In an embodiment, the duct module is formed of an insulating material and is coupled to each of the plurality of flow path parts. Therefore, the insulating between the plurality of flow path parts and the plurality of electrically connected parts located adjacent to them can be reliably formed.

Therefore, the size of the space required to electrically insulate the plurality of electrically connected parts and the plurality of flow path parts located adjacent to them is reduced. Accordingly, the duct module and the power conversion module including the same can be miniaturized.

In addition, according to the above configuration, the duct module and the power conversion module including the same according to the embodiment of the present disclosure can ensure the insulating between the components.

To begin with, the plurality of electrically connected parts that are respectively electrically connected to the external power source and the external load are disposed to be spaced apart from each other. In addition, the plurality of flow path parts disposed adjacent to the plurality of electrically connected parts are also disposed to be spaced apart from each other. Furthermore, a duct module formed of an insulating material is disposed between the plurality of flow path parts.

Therefore, the insulating between the plurality of electrically connected parts can be ensured. Furthermore, the electrical connection between the plurality of flow path parts may be blocked, and the insulating between them can also be ensured.

In addition, according to the above configuration, the duct module according to the embodiment of the present disclosure and the power conversion module including the same can be easily manufactured.

To begin with, a protrusion is provided in the duct body of the duct module. The protrusion is in contact with the end surface of the flow path part, thereby limiting the relative position between the duct body and the flow path part. The duct body and the flow path part are coupled by the flow path coupling part. The flow path coupling part is located at the end of the duct body.

When the flow path part and the duct body are located adjacent until the end surface of the flow path part contacts the protrusion, the flow path coupling part surrounds the end of the duct body and the end of the flow path part from the outside. In an embodiment, the flow path coupling part can be fixedly coupled to the duct body. The flow path coupling part and the flow path part can be coupled by a fastening member that penetratingly coupled from the outside toward the inside.

That is, the duct module and the flow path part can be coupled in a form in which the flow path part is inserted into the duct module. Furthermore, the insertion length of the flow path part may be limited by the contact between the end surface of the flow path part and the protrusion. Since the fastening member is coupled from the outside toward the inside of the duct module and the flow path part, the coupling process of the flow path part and the duct module can be easily performed.

Therefore, the manufacturing process of the duct module and the power conversion module including the same may be simplified.

It should be understood that the effects of the present disclosure are not limited to the above-described effects, and include all effects that can be inferred from the detailed description of the present disclosure or the configuration of the invention described in the claims.

### BRIEF DESCRIPTION OF THE DRAWINGS

FIG. 1 is a partially opened perspective view illustrating a power supply device according to an embodiment of the present disclosure.

FIG. 2 is a perspective view illustrating a power conversion module provided in the power supply device of FIG. 1.

FIG. 3 is a perspective view of another angle, illustrating the power conversion module of FIG. 2.

FIG. 4 is an exploded perspective view illustrating the power conversion module of FIG. 2.

FIG. 5 is an exploded perspective view of another angle illustrating the power conversion module of FIG. 2.

FIG. 6 is a perspective view illustrating a flow path part and a duct module provided in the power conversion module of FIG. 2.

FIG. 7 is an exploded perspective view illustrating the flow path part and the duct module of FIG. 6.

FIG. 8 is a perspective view illustrating a first flow path member of the flow path part of FIG. 6.

FIG. 9 is a perspective view illustrating the duct module of FIG. 6.

FIG. 10 is a perspective view illustrating a second flow path member of the flow path part of FIG. 6.

FIG. 11 is a cross-sectional view illustrating a flow path formed inside the flow path part and the duct module of FIG. 6.

### DETAILED DESCRIPTION

Hereinafter, embodiments of the present disclosure will be described in detail with reference to the accompanying drawings so that those skilled in the art can easily implement them. The present disclosure may be implemented in various different forms and is not limited to the embodiments described herein. In order to clearly explain the present disclosure, parts irrelevant to the description are omitted in the drawings, and the same or similar components are denoted by the same reference numerals throughout the entire specification.

The words and terms used in this specification and the claims are not interpreted as limited to ordinary or dictionary meanings, but should be interpreted as meanings and concepts consistent with the technical idea of the present disclosure according to the principle in which the inventor can define the terms and concepts in order to best explain their invention.

Therefore, the embodiments described in this specification and the configurations illustrated in the drawings correspond to a preferred embodiment of the present disclosure and do not all represent the technical idea of the present disclosure, so the corresponding configurations may be various equivalents and modifications to replace them at the time of filing the present disclosure.

In the following description, in order to clarify the features of the present disclosure, some components may be omitted.

### 1. Term Definition

The term “electrically connection” used in the following description means that two or more members are connected to transmit an electrical signal or current. In an embodiment, the electric-current-conducting may be formed in a wired form by a wire member or the like or in a wireless form such as RFID, Bluetooth, Wi-Fi or the like.

The term “communication” used in the following description means that two or more members are connected to each other so as to be in fluid communication. In one embodiment, the communication may be formed by a space formed inside the two or more members. Alternatively, the communication may be formed by a pipe, conduit, hose, or other member.

The term “fluid” used in the following description means any material that can be moved by external force or pressure and shape deformable according to the shape of the accommodated space. In an embodiment, the fluid may be provided in a gas phase or a liquid phase. In an embodiment, the fluid may be provided as air.

As used in the following description, the terms “upper side”, “lower side”. “front side”, “rear side”, “left side” and “right side” will be understood with reference to the coordinate system shown throughout the accompanying drawings.

### 2. Description of the Power Supply Device 1 According to an Embodiment of the Present Disclosure

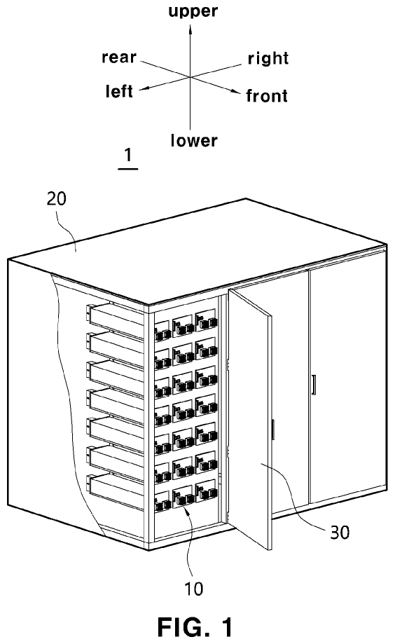

Referring to FIG. 1, a power supply device 1 according to an embodiment of the present disclosure is disclosed. The power supply device 1 is electrically connected to an external power source and an external load. The power supply device 1 may boost or drop the power transferred from the external power source to the external load.

In the illustrated embodiment, the power supply device 1 includes a power conversion module 10, a frame 20 and a door 30.

The power conversion module 10 substantially functions to boost or drop the transferred power. The power conversion module 10 is electrically connected to the external power source and the external load.

A plurality of power conversion modules 10 may be provided. The plurality of power conversion modules 10 may be configured to electrically connected to each other and boost or drop the power independently of each other. As the number of power conversion modules 10 is adjusted, the supply power of the power supply device 1 may be adjusted.

The power conversion modules 10 may be disposed adjacent to each other. In the illustrated embodiment, the plurality of power conversion modules 10 are disposed in parallel along the up-down direction and the left-right direction. The arrangement method of the power conversion modules 10 may be changed depending on the shape of the power supply device 1.

In particular, the power conversion modules 10 according to an embodiment of the present disclosure may effectively cool the heat generated in the process of boosting or dropping the supplied power. This will be described separately.

The power conversion modules 10 are accommodated inside the frame 20.

The frame 20 forms the outer shape of the power supply device 1. A space is formed inside the frame 20 so that various components of the power supply device 1 may be mounted. In an embodiment, the power conversion modules 10 may be accommodated in an inner space of the frame 20.

The frame 20 may be any shape capable of accommodating various components of the power supply device 1. In the illustrated embodiment, the frame 20 is in the shape of a square pillar, in which the front side is open.

The space of the frame 20 is opened and closed by the door 30. The door 30 is rotatably coupled to the open side of the frame 20, that is, the front side of the illustrated embodiment. As the door 30 rotates, the space may be opened or closed. The operator may access the power conversion modules 10 by manipulating the door 30.

Although not illustrated, a busbar (not show) may be provided to electrically connect the plurality of power conversion modules 10 to the outside. The busbar (not shown) may extend between the space and the outside of the frame 20 and may be electrically connected to external power and load.

In addition, the bus bar (not shown) is electrically connected to each of the plurality of power conversion modules 10, so that each of the plurality of power conversion modules 10 may be electrically connected to the external power source and load.

Since the method in which the plurality of power conversion modules 10 are electrically connected to the external power source and load by the bus bar (not shown) is a well-known technology, detailed description will be omitted.

The fluid to be described later, that is, fluid for cooling the components of the power conversion modules 10, may be a fluid that has stayed inside the frame 20. That is, the fluid may flow into the frame 20 and has undergone a filtering process at least one time.

Therefore, the fluid may be introduced into the power conversion modules 10 while dust or floating materials are removed. Accordingly, damage to the power conversion modules 10 by the fluid introduced for cooling may be prevented.

### 3. Description of the Power Conversion Module 10 According to an Embodiment of the Present Disclosure

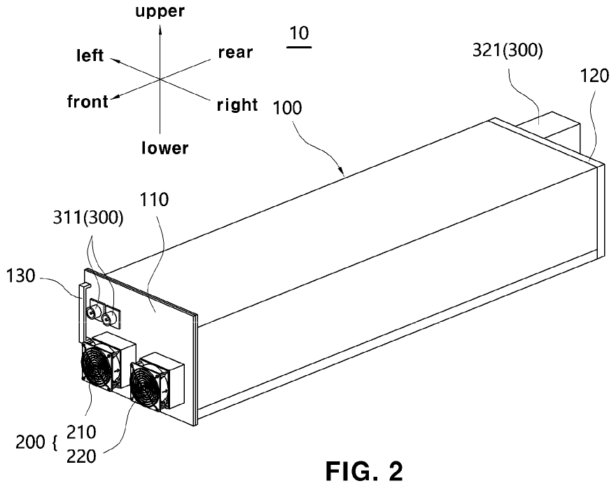

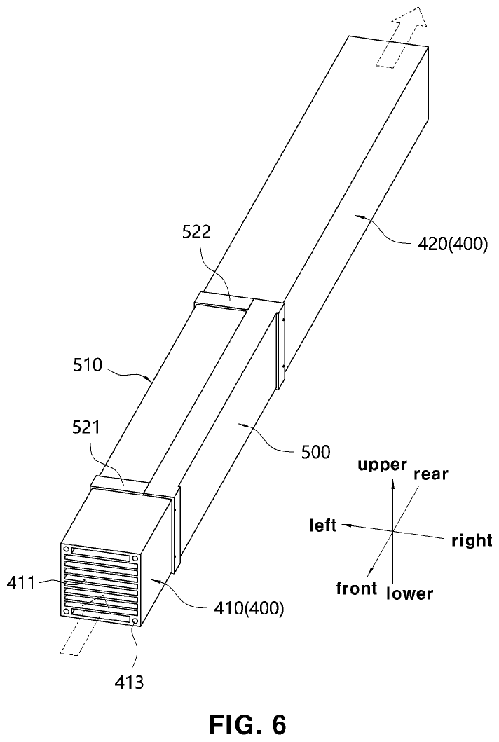

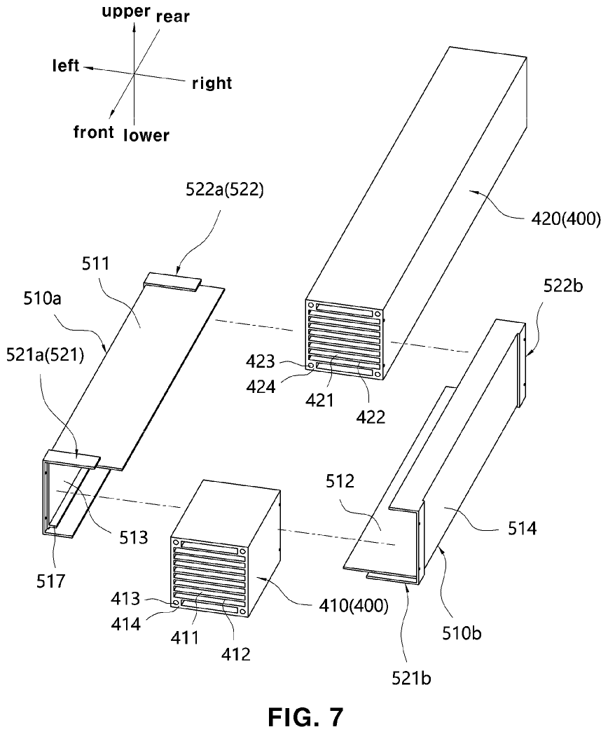

Referring to FIGS. 2 to 10, a power conversion module 10 according to an embodiment of the present disclosure is illustrated.

The power conversion module 10 according to an embodiment of the present disclosure may receive power from the external power source, and boost or drop the power source to transfer it to the external load. The power conversion module 10 may be provided modularized. That is, each of the plurality of power conversion modules 10 may perform a transforming operation. The plurality of power conversion modules 10 are electrically connected to each other, so that the total capacity of the power supply device 1 may be adjusted.

As the power conversion module 10 operates, a lot of heat is generated inside the power conversion module 10. When the generated heat stay inside the power conversion module 10, the components of the power conversion module 10 may be damaged by the heat. In addition, there is a risk that the operation efficiency of the power conversion module 10 may be lowered by the generated heat.

Accordingly, the power conversion module 10 according to the embodiment of the present disclosure is configured to effectively cool both the components of the high-pressure region and the components of the low-pressure region. Furthermore, the power conversion module 10 according to the embodiment of the present disclosure may improve cooling efficiency by simply forming a fluid flow path for cooling the components.

Hereinafter, the power conversion module 10 according to the embodiment of the present disclosure will be described with reference to the accompanying drawings. In the illustrated embodiment, the power conversion module 10 includes a housing 100, a blowing member 200, and an electrically connected part 300.

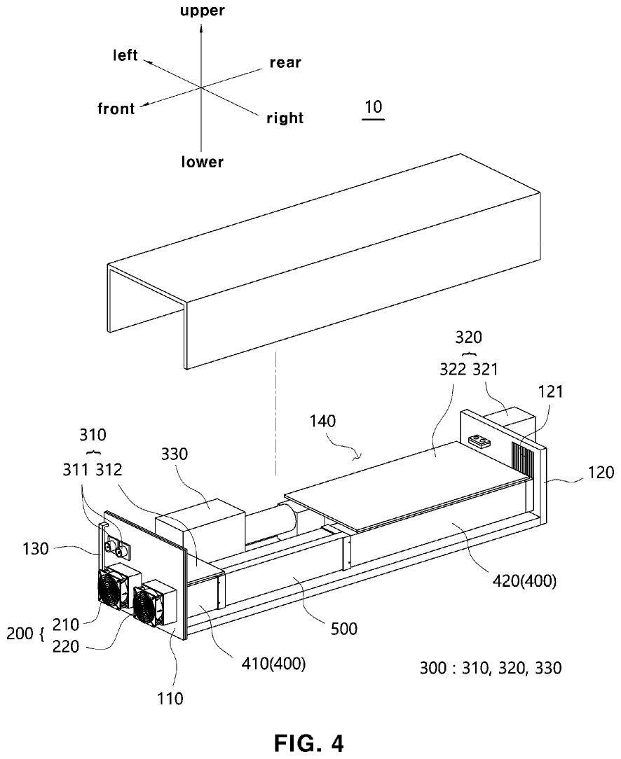

In addition, referring to FIGS. 4 to 7, the power conversion module 10 according to the illustrated embodiment further includes the flow path part 400 and the duct module 500, which will be described separately.

The housing 100 forms the outer shape of the power conversion module 10. The housing 100 is a portion where the power conversion module 10 is exposed to the outside. A space is formed inside the housing 100 so that the components of the power conversion module 10 may be accommodated. In an embodiment, the space of the housing 100 may accommodate the electrically connected part 300, the flow path part 400, and the duct module 500.

The housing 100 may be any shape that accommodates various components of the power conversion module 10 and may be accommodated in the frame 20. In the illustrated embodiment, the housing 100 has a square cross-section and is formed in a square pillar shape extending in the front-rear direction. It will be understood that the extending direction of the housing 100 is the same as the extending direction of the frame 20.

In particular, the power conversion module 10 according to the embodiment of the present disclosure may have a fluid for cooling its components flow along the extending direction of the housing 100. Accordingly, the fluid flow path may be simplified, and the cooling efficiency may be improved. This will be described later in detail.

The housing 100 may be separated in various forms. In the embodiment shown in FIG. 4, the housing 100 may be configured such that a portion forming an upper side thereof is separated from another portion. In the above embodiment, the components of the power conversion module 10 may be accommodated inside the housing 100 in the up-down direction.

Alternatively, the housing 100 may be opened by the first cover 110 and the second cover 120 to be described later, so that the components of the power conversion module 10 may be accommodated in the housing 100 in the extending direction of the housing 100, that is, the front-rear direction in the illustrated embodiment.

In the illustrated embodiment, the housing 100 includes a first cover 110, a second cover 120, a handle member 130, and an accommodation space 140.

The first cover 110 forms one end of the housing 100 in the extended direction, that is, a front end in the illustrated embodiment. The first cover 110 surrounds the space formed inside the housing 100, that is, the accommodation space 140, from the front side.

When the power conversion module 10 is accommodated in the frame 20, the first cover 110 is located in front of the frame 20. When the operator opens the door 30, the first cover 110 may be exposed to the user. Accordingly, various operating modules (not shown) for controlling the operation of the power conversion module 10 are provided in the first cover 110, and the first cover 110 may function as a control panel for the operator to control the power conversion module 10.

The blowing member 200 is coupled to the first cover 110. The blowing member 200 may operate in a state coupled to the first cover 110 to suck external outside air and flow it into an inner space of the housing 100.

A first electrically connected module 310 of the electrically connected part 300 may be coupled to the first cover 110. As illustrated in FIG. 2, a first terminal 311 of the first electrically connected module 310 may be partially exposed to the first cover 110. The first terminal 311 may be electrically connected to the outside so that power of a low-voltage may be electrically connected thereto.

A handle member 130 may be coupled to the first cover 110. An operator may grip the power conversion module 10, insert it into or withdraw it from the frame 20, using the handle member 130.

The first cover 110 forms one end of the housing 100, and may be provided in any form to which the blowing member 200 and the first electrically connected module 310 of the electrically connected part 300 may be coupled. In the illustrated embodiment, the first cover 110 is provided in the shape of a square plate with a width in the left-right directions, a height in the up-down direction, and a thickness in the front-rear direction.

The shape of the first cover 110 may be changed depending on the shape of the other components of the frame 20 and the housing 100.

In the illustrated embodiment, the first cover 110 includes a first inlet part 111 and a second inlet part 112.

The first inlet part 111 is formed through the first cover 110. The first inlet part 111 communicates with the outside of the housing 100 and the accommodation space 140.

The first fan 210 of the blowing member 200 may be disposed in the first inlet part 111 to generate a conveying force for introducing external fluid into the accommodation space 140. The introduced fluid may be heat-exchanged with the components of the power conversion module 10 accommodated in the accommodation space 140 and then discharged to the outside of the housing 100 through a first discharge part 121.

The first inlet part 111 is located adjacent to the second inlet part 112. In the illustrated embodiment, the first inlet part 111 is located at a left side of the second inlet part 112, which is due to the fact that the flow path portion 400 and the duct module 500 communicating with the second inlet 112 are located biased to the right side.

That is, the position of the first inlet part 111 may change depending on the positions of the second inlet part 112 and the flow path part 400 and duct module 500 communicating therewith.

In the illustrated embodiment, the first inlet part 111 is formed to have a square cross-section. The first fan 210 of the blowing member 200 may be disposed in the first inlet part 111 to generate a conveying force for sucking in external fluid.

The second inlet part 112 is formed through the first cover 110. The second inlet part 112 communicates with the flow path part 400 and the duct module 500 accommodated in the accommodation space 140 of the housing 100 to the outside.

The external fluid may pass through the second inlet part 112 by the conveying force provided by the second fan 220 of the blowing member 200 to enter the flow path part 400 and the duct module 500. The entering fluid may be heat-exchanged with the components of the power conversion module 10 and then discharged to the outside of the housing 100 through the second discharge part 122.

The second inlet part 112 is located adjacent to the first inlet part 111. In the illustrated embodiment, the second inlet part 112 is located at a right side of the first inlet part 111, which is due to the fact that the flow path portion 400 and the duct module 500 communicating with the second inlet 112 are located biased to the right side.

In other words, the position of the second inlet part 112 may change depending on the position of the first inlet part 111 and the positions of the flow path part 400 and the duct module 500 communicating with the second inlet part 112.

In the illustrated embodiment, the second inlet part 112 is formed to have a square cross-section. The second fan 220 of the blowing member 200 may be disposed in the second inlet part 112 to generate a conveying force for sucking in external fluid.

In the illustrated embodiment, the second inlet part 112 is formed to have a square cross-section. The second inlet part 112 may be divided into a plurality of spaces by the first partition member 412 of the first flow path member 410. This will be described later in detail.

The second cover 120 forms the other end of the housing 100 in the extended direction, that is, the rear end of the illustrated embodiment. The second cover 120 surrounds the space formed inside the housing 100, that is, the accommodation space 140, from the rear side.

When the power conversion module 10 is accommodated in the frame 20, the second cover 120 is located at the rear side of the frame 20. Therefore, even if the operator opens the door 30, the second cover 120 is located to be spaced apart from the operator.

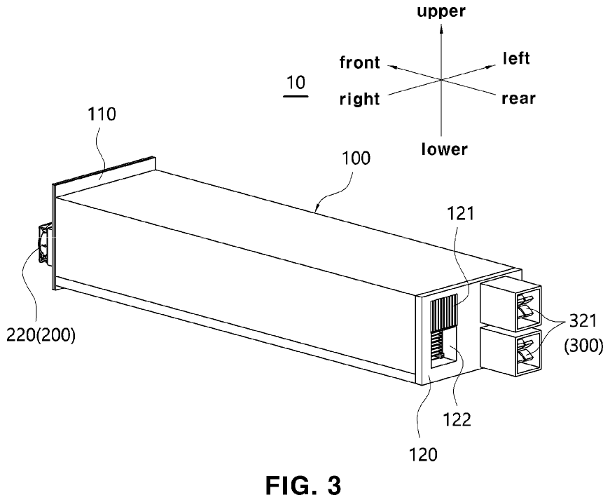

The second electrically connected module 320 of the electrically connected part 300 may be coupled to the second cover 120. As illustrated in FIG. 3, the second terminal 321 of the second electrically connected module 320 may be partially exposed to the second cover 120. The second terminal 321 may be electrically connected to the outside, and high-voltage power may be electrically connected thereto.

Thus, by the above arrangement, the operator may be physically spaced apart from the second electrically connected module 320 having a relatively high risk to prevent the occurrence of a safety accident.

In the illustrated embodiment, the second cover 120 includes a first discharge part 121 and a second discharge part 122.

The first discharge part 121 is formed through the second cover 120. The first discharge part 121 communicates with the outside of the housing 100 and the accommodation space 140. The fluid entering the accommodation space 140 of the housing 100 by the first fan 210 of the blowing member 200 may be heat-exchanged with the components of the power conversion module 10 and then discharged to the outside of the housing 100 through the first discharge part 121.

The first discharge part 121 is located adjacent to the second discharge part 122. In the illustrated embodiment, the first discharge part 121 is located at the upper side of the second discharge part 122, which is due to the fact that the flow path part 400 and the duct module 500 communicating with the second discharge part 122 are located on the lower side.

That is, the position of the first discharge part 121 may change depending on the positions of the second discharge part 122 and the flow path part 400 and duct module 500 communicating therewith.

In the illustrated embodiment, the first discharge part 121 is formed such that a plurality of openings extending in the up-down direction are adjacent to each other in the left-right direction. Alternatively, the first discharge part 121 may be extended in various directions, such as a left-right direction or a diagonal direction.

The second discharge part 122 is formed through the second cover 120. The second discharge part 122 communicates with the flow path part 400 and the duct module 500 accommodated in the accommodation space 140 of the housing 100 to the outside.

The fluid entering the flow path part 400 and the duct module 500 by the second fan 220 of the blowing member 200 may be heat-exchanged with the components of the power conversion module 10 and then discharged to the outside of the housing 100 through the second discharge part 122.

The second discharge part 122 is located adjacent to the first discharge part 121. The second discharge part 122 may be disposed at any position that may communicate with the flow path part 400 and the duct module 500. In the illustrated embodiment, the second discharge part 122 is located at the lower side of the first discharge part 121.

In the illustrated embodiment, the second discharge part 122 is formed to have a square cross-section. The second discharge part 122 may be divided into a plurality of spaces by the second partition member 422 of the second flow path member 420. This will be described later in detail.

The handle member 130 is a portion gripped by the operator. The operator may grip the handle member 130 to carry the power conversion module 10 or insert it into or withdraw it from the frame 20.

The handle member 130 is coupled to the first cover 110. The handle member 130 is extended from the first cover 110 toward the outside, that is, the front side in the embodiment shown. In the illustrated embodiment, the handle member 130 extends in the vertical direction, and is coupled to the first cover 110 at a plurality of points. The portion where the handle member 130 is coupled to the first cover 110 may be extended in the direction in which the housing 100 extends, that is, in the front-rear direction in the illustrated embodiment.

The accommodation space 140 is a space formed inside the housing 100. The accommodation space 140 is formed surrounded by the outer circumference of the housing 100, the first cover 110, and the second cover 120. The accommodation space 140 is not randomly exposed to the outside by the outer circumference of the housing 100, the first cover 110, and the second cover 120.

The components of the power conversion module 10 are accommodated in the accommodation space 140. In the illustrated embodiment, the electrically connected part 300, the flow path part 400, and the duct module 500 are accommodated in the accommodation space 140.

The accommodation space 140 is electrically connected to the outside. Specifically, the first electrically connected module 310 and the second electrically connected module 320 of the electrically connected part 300 accommodated in the accommodation space 140 may be electrically connected to external power source or load, respectively. The electrical connection may be formed by a conductive wire member (not shown) or the like.

The accommodation space 140 communicates with the outside. Specifically, the accommodation space 140 communicates with the outside by the first inlet part 111 and the first discharge part 121 formed in the first cover 110. The fluid for cooling the components of the power conversion module 10 may be introduced into the accommodation space 140 by the first inlet part 111 and the first fan 210 disposed thereon.

The introduced fluid flows in the accommodation space 140 and heat-exchanges with the components of the power conversion module 10 to cool the components. The heat-exchanged fluid may be discharged to the outside of the accommodation space 140 through the first discharge part 121.

The accommodation space 140 may be formed in a shape corresponding to the shape of the housing 100. In the illustrated embodiment, the housing 100 has a square cross-section and has a square pillar shape extending in the front-rear direction, and the accommodation space 140 has a hollow shape formed inside the square pillar.

A detailed description of the process in which the components of the power conversion module 10 are cooled by fluid flowing in the accommodation space 140 will be described later.

The blowing member 200 generates a conveying force to flow fluid outside the housing 100 to the accommodation space 140 or the flow path part 400 and the duct module 500. The external fluid may be continuously introduced into the accommodation space 140 or the flow path part 400 and the duct module 500 by the conveying force.

Accordingly, a process in which external fluid may be introduced into the accommodation space 140 or the flow path part 400 and the duct module 500, performs heat exchange, and is then discharged may proceed continuously.

As a result, as the blowing member 200 operates, the cooling process of the components of the power conversion module 10 progresses continuously, thereby enabling stable operation of the power conversion module 10.

The blowing member 200 may be provided in any form that may provide the conveying power to the fluid. In the illustrated embodiment, the blowing member 200 is provided as a fan including a plurality of blades.

The blowing member 200 is rotatably coupled to the housing 100. The blowing member 200 may be coupled to one end of the housing 100 in the extending direction. In the illustrated embodiment, the blowing member 200 is rotatably coupled to the first cover 110 located on the front side.

The blowing member 200 may be electrically connected to the external power source to receive power and control signals for operation.

A plurality of blowing members 200 may be provided. The plurality of blowing members 200 may generate a conveying force to allow external fluid to flow to the accommodation space 140 and the flow path part 400 (and the duct module 500 communicating with the flow path part 400), respectively.

In the illustrated embodiment, two blowing members 200 are provided, including the first fan 210 and the second fan 220.

The first fan 210 generates the conveying force for introducing external fluid into the accommodation space 140. The first fan 210 is rotatably coupled to the first cover 110.

The first fan 210 may be located on a flow path in communication with the outside and the accommodation space 140. In the illustrated embodiment, the first fan 210 is located on the first inlet part 111. As the first fan 210 operates, the external fluid may flow into the accommodation space 140 through the first inlet part 111.

A second fan 220 is located adjacent to the first fan 210.

The second fan 220 generates a conveying force for introducing external fluid into the flow path part 400 and the duct module 500 communicating with the flow path part 400. The second fan 220 is rotatably coupled to the first cover 110.

The second fan 220 may be located on the flow path in which the flow path 400 or the duct module 500 communicates with the outside. In the illustrated embodiment, the second fan 220 is located on the second inlet part 112. As the second fan 220 operates, external fluid may flow into the flow path part 400 and the duct module 500 through the second inlet part 112.

Whether the first fan 210 and the second fan 220 rotate or not, the rotation direction, and the rotation speed, may be controlled independently of each other. Accordingly, different flow rates of fluid may flow and heat-exchange with other components depending on the operating state of the power conversion module 10 in the accommodation space 140 and the flow path part 400 (and the duct module 500 communicating with the flow path part 400).

The electrically connected part 300 is a component in which the power conversion module 10 is electrically connected to an external power source and load. The electrically connected part 300 may be electrically connected to the external power source, the external load, and the other power conversion module 10 by the above-described bus bar (not shown).

The electrically connected part 300 substantially plays a role of boosting or dropping the received power.

In an embodiment, the electrically connected part 300 may be configured to receive high-voltage, low-frequency alternating current (AC) and output low-voltage direct current (DC) by frequency conversion, boosting, or dropping. To this end, the electrically connected part 300 may include a plurality of electrically connected modules 310 and 320 to control high-pressure alternating current and low-pressure direct current, respectively.

In this case, the characteristics of the current that is electrically connected to the plurality of electrically connected modules 310 and 320 may be changed. In other words, in the following description, it is assumed that the first electrically connected module 310 is electrically connected to the external load to transfer a low-voltage direct current to the external load, and the second electrically connected module 320 is electrically connected to the external power source to receive a high-voltage, low-frequency alternating current.

Alternatively, the first electrically connected module 310 may be configured to be electrically connected to the external power source to receive low-voltage direct current, and the second electrically connected module 320 may be configured to be electrically connected to the external load to transfer high-voltage, low-frequency alternating current.

The electrically connected part 300 is coupled to the housing 100. Some components of the electrically connected part 300 may be coupled to the first cover 110 or the second cover 120 and partially exposed to the outside. Through the portion exposed to the outside, the electrical electrically connected part 300 may be electrically connected to the external power source or load.

Other components of the electrically connected part 300 are accommodated in the accommodation space 140. The other components of the electrically connected part 300 may be electrically connected to some of the components.

In the illustrated embodiment, the electrically connected part 300 includes the first electrically connected module 310, the second electrically connected module 320, and a voltage-transforming module 330.

One of the first electrically connected module 310 and the second electrically connected module 320 may be electrically connected to the external power source to receive power to be transformed, and the other may be electrically connected to the external load to transfer transformed power. Hereinafter, it will be explained on the premise that the electrically connected part 300 converts and drops the frequency of the received power and transfers it to the outside.

The first electrically connected module 310 may transfer power that is electrically connected to the external load and is dropped. In an embodiment, the first electrically connected module 310 may be electrically connected to the power that is dropped, that is, the power that is low-voltage. In the above embodiment, the first electrically connected module 310 may be referred to as a “low-voltage module”. At this time, the power transferred by the first electrically connected module 310 to the external load may be direct current power at a low-voltage.

In the following, it will be explained on the premise that the first electrically connected module 310 is electrically connected to low-voltage power, that is, the dropped power.

The first electrically connected module 310 is electrically connected to the external load. The dropped power (i.e., low-voltage power) may be transferred to the external load through the first electrically connected module 310.

The first electrically connected module 310 is electrically connected to the voltage-transforming module 330. In addition, the first electrically connected module 310 is electrically connected to the second electrically connected module 320 through the voltage-transforming module 330. The power transferred to the second electrically connected module 320 may be dropped by the voltage-transforming module 330 and transferred to the first electrically connected module 310. In this case, the power transferred from the voltage-transforming module 330 to the first electrically connected module 310 may be direct current power at a low-voltage.

The first electrically connected module 310 is partially accommodated in the accommodation space 140. In other words, some components of the first electrically connected module 310 may be exposed to the outside of the housing 100, and other components of the first electrically connected module 310 may be accommodated in the accommodation space 140.

The first electrically connected module 310 may be located biased to one side of the accommodation space 140. In other words, the first electrically connected module 310 may be located biased to any one of the first cover 110 and the second cover 120. In the illustrated embodiment, the first electrically connected module 310 is located biased to the first cover 110 located in the front side. The first electrically connected module 310 is located adjacent to the first cover 110.

As described above, the first cover 110 is a portion located adjacent to the operator who approaches the power supply device 1. As relatively low-voltage power is electrically connected to the first electrically connected module 310 located adjacent to the first cover 110, the possibility of a safety accident occurring may be reduced.

In addition, in the embodiment in which the electrically connected part 300 is configured to drop the power, frequent adjustment of low-voltage power may be required depending on the situation of the load. The first electrically connected module 310 to which low-voltage power is electrically connected is disposed adjacent to the first cover 110 located in the front side, the operator may variously adjust output power, that is, low-voltage power, by using various manipulation modules (not shown) disposed on the first cover 110 as necessary.

The first electrically connected module 310 is located adjacent to the flow path part 400. Specifically, the first electrically connected module 310 is located adjacent to the first cover 110, that is, the first flow path member 410 located biased to the front side.

In an embodiment, the first electrically connected module 310 may be disposed to be in contact with the first flow path member 410. Accordingly, the heat generated by the first electrically connected module 310 may be rapidly and highly transmitted to the first flow path member 410, thereby improving the cooling efficiency of the first electrically connected module 310.

The first electrically connected module 310 may include any component for receiving low-voltage power from the voltage-transforming module 330 and transferring the received low-voltage power to the external load. In an embodiment, the first electrically connected module 310 may be provided to include a plurality of switching elements.

In the illustrated embodiment, the first electrically connected module 310 includes the first terminal 311 and a first PCB 312.

The first terminal 311 is electrically connected to the external load and transfers the received low-voltage power (i.e., low voltage DC power) to the external load. The first terminal 311 is electrically connected to the external load and voltage-transforming module 330.

The first terminal 311 may be exposed to the outside of the housing 100. The first terminal 311 may penetrate any one of the first cover 110 and the second cover 120 and be exposed to the outside. In the illustrated embodiment, the first terminal 311 penetrates the first cover 110 located in the front side and is exposed to the outside.

A plurality of first terminals 311 may be provided. The plurality of first terminals 311 may be connected to external loads, respectively. In the illustrated embodiment, two first terminals 311 are provided and disposed to be spaced apart from each other along the left-right direction.

The first terminal 311 may be located biased to one side of the first cover 110 in the height direction. In the illustrated embodiment, the first terminal 311 is located biased to the upper side of the first cover 110, which is due to the fact that the first PCB 312 is located at the upper side of the first flow path member 410. The position of the first terminal 311 may change depending on the position of the first PCB 312.

The first PCB 312 operates by receiving a control signal for controlling the operation of the first electrically connected module 310. The first PCB 312 may be electrically connected to an external manipulation module (not shown) to receive the control signal.

The first PCB 312 is electrically connected to the first terminal 311. According to the operation of the first PCB 312, the electrical connection between the first terminal 311 and the external load or the voltage-transforming module 330 may be controlled. Since the process of controlling the electrical connection of low-voltage power by the first PCB 312 is well-known, detailed descriptions will be omitted.

The first PCB 312 is accommodated in the accommodation space 140. The first PCB 312 may be located biased to one side of the extending direction of the accommodation space 140. In the illustrated embodiment, the first PCB 312 is located biased to the front side of the accommodation space 140 and is located adjacent to the first cover 110.

The first PCB 312 is located adjacent to the flow path part 400. Specifically, the first PCB 312 is located adjacent to the first flow path member 410, which is located biased to the front side. The first PCB 312 may be disposed at any position adjacent to the first flow path member 410. In the illustrated embodiment, the first PCB 312 is located in the upper side of the first flow path member 410.

In an embodiment, the first PCB 312 may be in contact with the first flow path member 410. In the above embodiment, the first flow path member 410 may function as a heat sink that directly receives heat generated in the first PCB 312.

The first electrically connected module 310 may be heat-exchanged with each fluid introduced into the accommodation space 140 and the flow path part 400 and cooled. This will be described later in detail.

The second electrically connected module 320 may be electrically connected to the external power source to receive high-voltage power. In an embodiment, the second electrically connected module 320 may be electrically connected to power to be frequency converted and dropped, that is, high-voltage power. In the above embodiment, the second electrically connected module 320 may be referred to as a “high-voltage module”. At this time, the power transferred to the second electrically connected module 320 may be high-voltage, low frequency alternating electric power.

In the following, it will be explained on the premise that the high-voltage power, that is, the power to be dropped, is electrically connected to the second electrically connected module 320.

The second electrically connected module 320 is electrically connected to the external power source. High-voltage, low-frequency alternating current power (i.e., high-voltage power) to be dropped, may be transferred from the external power source through the second electrically connected module 320.

The second electrically connected module 320 is electrically connected to the voltage-transforming module 330. In addition, the second electrically connected module 320 is electrically connected to the first electrically connected module 310 through the voltage-transforming module 330. The power transferred to the second electrically connected module 320 may be frequency converted by the second electrically connected module 320 into high-frequency alternating power and then transferred to the voltage-transforming module 330.

The second electrically connected module 320 is partially accommodated in the accommodation space 140. In other words, some components of the second electrically connected module 320 may be exposed to the outside of the housing 100, and other components of the second electrically connected module 320 may be accommodated in the accommodation space 140.

The second electrically connected module 320 may be located biased to the other side of the accommodation space 140. In other words, the second electrically connected module 320 may be located biased to the other of the first cover 110 and the second cover 120. In the illustrated embodiment, the second electrically connected module 320 is located biased to the second cover 120 located on the rear side. The second electrically connected module 320 is located adjacent to the second cover 120.

As described above, the second cover 120 is a portion located to be spaced apart from the operator approaching the power supply device 1. In other words, since the second electrically connected module 320 disposed to be spaced apart from the operator is electrically connected to relatively high-voltage power, the possibility of a safety accident occurring may be reduced.

In addition, in an embodiment in which the electrically connected part 300 is configured to drop power, high-voltage power is applied from the external power source to the power conversion module 10. Therefore, the second electrically connected module 320 to which high-voltage power is electrically connected may be sufficient only by relatively less frequent adjustment compared to the first electrically connected module 310 to which low-voltage power is electrically connected. As a result, efficient operation of the power supply device 1 may also be enabled while securing safety of the operator.

The second electrically connected module 320 is located adjacent to the flow path part 400. Specifically, the second electrically connected module 320 is located adjacent to the second cover 120, that is, the second flow path member 420 located biased to the rear side.

In an embodiment, the second electrically connected module 320 may be disposed to be in contact with the second flow path member 420. Accordingly, the heat generated by the second electrically connected module 320 may be rapidly and highly transmitted to the second flow path member 420, thereby improving the cooling efficiency of the second electrically connected module 320.

The second electrically connected module 320 may include any component for receiving high-voltage power from the external power source, frequency converting the received power, and transferring it to the voltage-transforming module 330. In an embodiment, the second electrically connected module 320 may be provided to include a plurality of switching elements.

In the illustrated embodiment, the second electrically connected module 320 includes the second terminal 321 and a second PCB 322.

The second terminal 321 is electrically connected to the external power source to receive high-voltage power (i.e., high-voltage, low-frequency alternating current power). The received high-voltage, low-frequency power is frequency converted into high-voltage, high-frequency alternating electric power by the second electrically connected module 320 and then transferred to the voltage-transforming module 330. The second terminal 321 is electrically connected to the external power source and the voltage-transforming module 330.

The second terminal 321 may be exposed to the outside of the housing 100. The second terminal 321 may penetrate the other of the first cover 110 and the second cover 120 and be exposed to the outside. In the illustrated embodiment, the second terminal 321 penetrates the second cover 120 located in the rear side and is exposed to the outside.

A plurality of second terminals 321 may be provided. The plurality of second terminals 321 may be connected to the external power source. In the illustrated embodiment, two second terminals 321 are provided and disposed to be spaced apart from each other along the up-down direction.

The second terminal 321 may be located biased to one side of the second cover 120 in the width direction. In the illustrated embodiment, the second terminal 321 is located biased to the left side of the second cover 120, which is due to the fact that the second PCB 322 is located on the left side of the second flow path member 420. The position of the second terminal 321 may change depending on the position of the second PCB 322.

The second PCB 322 operates by receiving a control signal for controlling the operation of the second electrically connected module 320. The second PCB 322 may be electrically connected to an external manipulation module (not shown) to receive the control signal.

The second PCB 322 is electrically connected to the second terminal 321. According to the operation of the second PCB 322, the electrical connection between the second terminal 321 and the external power source or the voltage-transforming module 330 may be controlled. Since the process of controlling the electrical connection of high-voltage power by the second PCB 322 is well-known, detailed descriptions will be omitted.

The second PCB 322 is accommodated in the accommodation space 140. The second PCB 322 may be located biased to the other side of the extending direction of the accommodation space 140. In the illustrated embodiment, the second PCB 322 is located biased to the rear side of the accommodation space 140 and is located adjacent to the second cover 120.

The second PCB 322 is located adjacent to the flow path part 400. Specifically, the second PCB 322 is located adjacent to the second flow path member 420, which is located biased to the rear side. The second PCB 322 may be disposed at any position adjacent to the second flow path member 420. In the illustrated embodiment, the second PCB 322 is located on the upper side of the second flow path member 420.

In an embodiment, the second PCB 322 may be in contact with the second flow path member 420. In the above embodiment, the second flow path member 420 may function as a heat sink that directly receives heat generated in the second PCB 322.

The second electrically connected module 320 may be heat-exchanged with each fluid introduced into the accommodation space 140 and the flow path part 400 and cooled.

This will be described later in detail.

The above-described first electrically connected module 310 and second electrically connected module 320 may be disposed to be physically and electrically spaced apart from each other. That is, the first electrically connected module 310 and the second electrically connected module 320 are not in direct contact or electrically connected directly to each other.

In addition, the above-described first electrically connected module 310 and the second electrically connected module 320 may be disposed to be spaced apart from each other along the extending direction of the housing 100. In the illustrated embodiment, the first electrically connected module 310 and the second electrically connected module 320 are disposed to be spaced apart from each other along the front-rear direction.

As will be described later, the flow path part 400 and the duct module 500 according to the embodiment of the present disclosure may be disposed in the same direction as the direction in which the first electrically connected module 310 and the second electrically connected module 320 are spaced apart.

Accordingly, the flow path formed inside the flow path part 400 and the duct module 500 may also extend in the same direction as the direction, that is, in the front-rear direction, in the illustrated embodiment. As a result, the flow of fluid for cooling may be simplified, thereby improving cooling efficiency, and miniaturizing the power conversion module 10. This will be described later in detail.

The voltage-transforming module 330 receives high-voltage, high-frequency alternating electric power from the second electrically connected module 320 and drops it to low-voltage, high-frequency alternating power. The dropped power may be transferred to the external load through the first electrically connected module 310. The voltage-transforming module 330 may be provided in any form that may receive power of one voltage and convert it into power of another voltage.

The voltage-transforming module 330 is electrically connected to the first electrically connected module 310. The low-voltage, high-frequency alternating electric power dropped by the voltage-transforming module 330 may be transferred to the first electrical power module 310.

The voltage-transforming module 330 is electrically connected to the second electrically connected module 320. The high-voltage, high-frequency alternating power converted by the second electrically connected module 320 may be transferred to the voltage-transforming module 330.

The voltage-transforming module 330 is accommodated in the accommodation space 140. The voltage-transforming module 330 is surrounded by the outer circumference of the housing 100 and is not randomly exposed to the outside.

The voltage-transforming module 330 is located adjacent to the first electrically connected module 310 and the second electrically connected module 320. In an embodiment, the voltage-transforming module 330 may be located between the first electrically connected module 310 and the second electrically connected module 320 along the extending direction of the housing 100.

In the above embodiment, a member for electrical connection between the voltage-transforming module 330 and the first and second electrically connected modules 310 and 320 may be minimized. Furthermore, the size of the space occupied by the electrically connected part 300 may be reduced, making it possible to miniaturize the power conversion module 10.

The voltage-transforming module 330 is located adjacent to the duct module 500. In the illustrated embodiment, the voltage-transforming module 330 is located on the left side of the duct module 500. The voltage-transforming module 330 may be disposed at any position that may be electrically connected to the first electrically connected module 310 and the second electrically connected module 320.

Although not illustrated, the outer circumferential surface of the voltage-transforming module 330 may be configured to include a plurality of concave portions and convex portions. In the above embodiment, a creepage distance of the outer circumferential surface of the voltage-transforming module 330 may be increased, so that the creepage distance sufficient for insulating may be secured.

The above-described electrically connected part 3X) was assumed to frequency convert and drop the received power. Alternatively, the electrically connected part 300 may be configured to frequency convert and boost the received power, and in this case, it will be understood that the electrical connection direction is formed opposite to the electrical connection direction according to the above description.

That is, in the alternative embodiment, the power to be transformed may be transferred to the first electrically connected module 310, then boosted through the voltage-transforming module 330, and transferred to the outside through the second electrically connected module 320.

The above-described function of the electrically connected part 300 will be described based on the electrical connection direction of the power. In the following description, it is assumed that the power applied from the external power source through the second electrically connected module 320 is transferred to the external load through the voltage-transforming module 330 and the first electrically connected module 310.

First, high-voltage, low-frequency alternating current power is transferred from the external power source to the second electrically connected module 320. The second electrically connected module 320 frequency converts the high-voltage, low-frequency alternating current power into high-voltage, high-frequency alternating current power.

The frequency-converted high-voltage, high-frequency alternating current power is transferred to the voltage-transforming module 330. The voltage-transforming module 330 drops the high-voltage, high-frequency alternating current power into the low-voltage, high-frequency alternating current power.

The dropped low-voltage, high-frequency alternating current power is transferred to the first electrically connected module 310. The first electrically connected module 310 frequency converts the low-voltage, high-frequency alternating current power into the low-voltage, low-frequency alternating current power. At this time, the first electrically connected module 310 may convert the frequency of the converted power into zero, that is, the low-voltage direct current power. The converted low-voltage direct current power is transferred to the external load.

### 4. Description of the Flow Path Part 400 and the Duct Module 500 of the Power Conversion Module 10 According to an Embodiment of the Present Disclosure

Referring again to FIGS. 4 to 7, the power conversion module 10 according to an embodiment of the present disclosure present involves the flow path part 400 and the duct module 500. The flow path part 400 and the duct module 500 function as a passage for discharging heat generated as the power conversion module 10 operates.

The flow path part 400 and the duct module 500 communicate with the outside to allow external fluid to be introduced into the flow path part 400 and the duct module 500. The introduced air heat-exchanges with the flow path part 400 and cools the components of the power conversion module 10 before being discharged to the outside again.

As will be described later, a plurality of flow path portions 400 may be provided and may be disposed adjacent to the first electrically connected module 310 and the second electrically connected module 320, respectively. The fluid for cooling the first and second electrically connected modules 310 and 320 may flow inside the plurality of flow path parts 400. The duct module 500 may communicate with a plurality of flow path parts 400 to form a single flow path through which the fluid may flow.

In particular, the flow path part 400 and the duct module 500 according to the embodiment of the present disclosure may be arranged side by side along one direction, and the flow path formed therein may also be formed along the one direction. Therefore, the flow of fluid for cooling the components of the power conversion module 10 may be simplified, and the flow rate and heat-exchange efficiency may be improved.

As described above, the accommodation space 140 of the housing 100 may communicate with the outside at a plurality of locations.

That is, the external fluid may be directly introduced into the accommodation space 140 through the first inlet part 111 formed in the first cover 110. In addition, the external fluid may be introduced into the flow path part 400 and the duct module 500 through the second inlet part 112 formed in the first cover 110.

Therefore, in the following description, the fluid flowing into the flow path part 400 and the duct module 500 through the second inlet part 112 among external fluids is mainly described.

Hereinafter, referring to FIGS. 4 to 10, the flow path part 400 and the duct module 500 according to an embodiment of the present disclosure will be described in detail.

The flow path part 400 forms a flow path of fluid that flows to cool the components of the power conversion module 10 together with the duct module 500. The flow path part 400 communicates with the outside of the housing 100 and the duct module 500, respectively.

The flow path part 400 is accommodated in the accommodation space 140. The flow path part 400 may be located biased to one space of the accommodation space 140. In the illustrated embodiment, the flow path part 400 is located biased to the right side of the accommodation space 140.

The flow path part 400 communicates with the outside through the first cover 110. Specifically, the flow path part 400 communicates with the outside through the second inlet part 112 formed in the first cover 110. The external fluid may flow into the flow path part 400 through the second inlet part 112.

The flow path part 400 communicates with the outside through the second cover 120. Specifically, the flow path part 400 communicates with the outside through the second discharge part 122 formed in the second cover 120. The heat-exchanged fluid may be discharged to the outside of the housing 100 through the second discharge part 122.

The flow path part 400 is located adjacent to the blowing member 200. Specifically, among the portions of the flow path part 400, the portion communicating with the second inlet part 112, that is, the front end in the illustrated embodiment, is located adjacent to the second fan 220. When the second fan 220 operates, the external fluid is introduced into the flow path part 400 through the second inlet part 112 as described above.

The flow path part 400 is located adjacent to the electrically connected part 300. In an embodiment, the flow path part 400 may be disposed to be in contact with the electrically connected part 300. In the above embodiment, the heat generated by the electrically connected part 300 is quickly transmitted to the flow path part 400, so that the cooling efficiency of the electrically connected part 300 may be improved.

As described above, a plurality of electrically connected parts 300 may be provided, including the first electrically connected module 310 and second electrically connected module 320. Therefore, a plurality of flow path parts 400 may also be provided, including the first flow path member 410 and the second flow path member 420, and may be located adjacent to the first and second electrically connected modules 310 and 320, respectively.

In the above embodiment, a plurality of flow path parts 400 may each communicate with the duct modules 500.

The flow path part 400 may be formed of a material having high thermal conductivity. The cooling efficiency of the electrically connected part 300 is improved by receiving heat generated from the electrically connected part 300 quickly and transmitting the heat to the fluid flowing inside. In an embodiment, the flow path part 400 may be formed of aluminum (Al) or copper (Cu) material.

The flow path part 400 may have a space in which fluid may flow, heat-exchange with the electrically connected part 300, and may be any shape capable of transmitting the received heat to the fluid flowing. In the illustrated embodiment, the flow path part 400 has a square cross-section and is a square pillar shape extending in the front-rear direction.

In the illustrated embodiment, the flow path part 400 includes the first flow path member 410 and the second flow path member 420.

The first flow path member 410 is located adjacent to any one of the first and second electrically connected modules 310 and 320, and is configured to heat-exchange with the one electrically connected module. That is, the first flow path member 410 is configured to cool the any one electrically connected module.

In the illustrated embodiment, the first flow path member 410 is located adjacent to the first electrically connected module 310 located at the front side, and is configured to receive the heat of the first electrically connected module 310.

The first flow path member 410 may extend in the same direction as the extending direction of the housing 100. In the illustrated embodiment, the first flow path member 410 is formed to extend in the front-rear direction.

In this case, the extension length of the first flow path member 410 may be shorter than the extension length of the second flow path member 420. This is due to the fact that the first electrically connected module 310 disposed adjacent to the first flow path member 410 generates relatively less heat compared to the second electrically connected module 320 disposed adjacent to the second flow path member 420.

That is, in the embodiment of the present disclosure, the first electrically connected module 310 electrically connected to the external load is configured to output the low-voltage direct current power without a conversion process to alternating current power. Therefore, additional components (e.g., switching elements) for frequency converting DC power into AC power are not required. Accordingly, the amount of heat generated in the first electrically connected module 310 is reduced compared to the case where the additional components are provided.

On the other hand, the second electrically connected module 320 electrically connected to the external power source requires components for frequency converting the received high-voltage, low-frequency AC power into high-voltage, high-frequency AC power. Therefore, the amount of heat generated in the second electrically connected module 320 is greater than the amount of heat generated in the first electrically connected module 310.

Accordingly, the amount of fluid required for cooling also increases, and the length of the second flow path member 420 disposed adjacent to the second electrically connected module 320 is formed to be longer.

Therefore, it will be understood that the extension lengths of the first flow path member 410 and the second flow path member 420 may vary in size depending on the number of switching elements provided in each of the first and second electrically connected modules 310 and 320.

That is, alternatively, if the number of switching elements provided in the first electrically connected module 310 is greater than the number of switching elements provided in the second electrically connected module 320, the extension length of the first flow path member 410 may be formed longer than the extension length of the second flow path member 420.

The extension length of the first flow path member 410 may be changed depending on the flow distance of the fluid required for cooling the first electrically connected module 310.

The first flow path member 410 is coupled with the first cover 110. The one end of the extending direction of the first flow path member 410, that is, the front end in the illustrated embodiment, is coupled to the first cover 110.

The first flow path member 410 communicates with the second inlet part 112 formed in the first cover 110. The space formed inside the one end of the first flow path member 410 in the extending direction, that is, the front end in the illustrated embodiment, communicates with the second inlet part 112.

The first flow path member 410 is coupled to the duct module 500. The other end of the first flow path member 410 in the extending direction, that is, the rear end in the illustrated embodiment, are coupled to the duct module 500.

The first flow path member 410 communicates with the duct module 500. The space formed inside the other end of the first flow path member 410 in the extending direction, that is, the rear end in the illustrated embodiment, communicates with the duct space 515 of the duct module 500.

The first flow path member 410 is disposed to face the second flow path member 420 with the duct module 500 interposed therebetween. In other words, in the embodiment shown in FIG. 4, the first flow path member 410, the duct module 500, and the second flow path member 420 are arranged in order from the front side to the rear side.

The first flow path member 410 is located adjacent to the first electrically connected module 310. In an embodiment, the first flow path member 410 may be disposed to be in contact with a component of the first electrically connected module 310, for example, the first PCB 312. In the above embodiment, the first flow path member 410 may function as a heat sink of the first electrically connected module 310 as described above.

In the illustrated embodiment, the first flow path member 410 includes a first flow path space 411, a first partition member 412, a first fan fastening hole 413, and a first support wall 414.

The first flow path space 411 is a space formed inside the first flow path member 410. The first flow path space 411 functions as a passage through which the introduced external fluid flows.

The first flow path space 411 extends in the extending direction of the first flow path member 410, that is, in the front-rear direction in the illustrated embodiment. Each end of the first flow path space 411 in the extending direction, that is, the front end and the rear end in the illustrated embodiment, are each open. The front end of the first flow path space 411 communicates with the second inlet part 112. The rear end of the first flow path space 411 communicates with the duct space 515 of the duct module 500.

The first flow path space 411 may be any shape in which the introduced external fluid may flow. In the illustrated embodiment, the first flow path space 411 has a square cross-section corresponding to the shape of the first flow path member 410 and is formed in a square pillar extending in the front-rear direction.

A first partition member 412 is disposed in the first flow path space 411.

The first partition member 412 divides the first flow path space 411 into a plurality of spaces. The plurality of spaces divided by the first partition member 412 may be physically spaced apart from each other, so that a passage through which the introduced fluid flows may be formed independently.

The first partition member 412 extends in the extending direction of the first flow path member 410, that is, in the front-rear direction in the illustrated embodiment. Each end of the first partition member 412 in the extending direction, that is, the front end and the rear end in the illustrated embodiment, may be disposed on the same plane as each end of the first flow path member 410 in the extending direction. In other words, the first partition member 412 may extend from the first flow path space 411 by the same length as the first flow path member 410.

As the front end of the first partition member 412 is formed adjacent to the second inlet part 112, the fluid flowing through the second inlet part 112 may be divided into a plurality of flows by the first partition member 412 and enter the first flow space 411.

The first partition member 412 may be provided in a plate shape. In the illustrated embodiment, the first partition member 412 is provided in the shape of a square plate having a width by the width (i.e., the length in the left-right direction) of the first flow path space 411 and extending by the length (i.e., the length in the front-rear direction) of the first flow path member 410 and having a thickness in the height (i.e., the length in the up-down direction) direction of the first flow path member 410.

In this case, the cross-section of the first partition member 412 may be formed to be smaller than the cross-section of each space into which the first flow path space 411 is divided.

A plurality of first partition members 412 may be provided. The plurality of first partition members 412 may be spaced apart from each other, and a space in which the first flow path space 411 is partitioned may be disposed between the adjacent first partition members 412.

In the illustrated embodiment, the plurality of first partition members 412 extend in the width direction, that is, the left-right direction, of the first flow path member 410, and are disposed to be spaced apart from each other in the height direction, that is, the up-down direction, of the first flow path member 410. In this case, a plurality of spaces partitioned by the plurality of first partition members 412 extend in the left-right direction.

Alternatively, the plurality of first partition members 412 may be extended in the height direction, that is, the up-down direction, of the first flow path member 410, and may be disposed to be spaced apart from each other in the width direction, that is, left-right direction of the first flow path member 410. In the above embodiment, a plurality of spaces partitioned by the plurality of first partition members 412 may be formed to extend in the up-down direction.

In an embodiment, the plurality of first partition members 412 may extend parallel to each other. In the above embodiment, the amount of fluid flowing in the plurality of partitioned spaces may be uniformly adjusted with each other.

As the first flow path space 411 is divided into a plurality of spaces having a smaller cross-sectional area by the plurality of first partition members 412, the fluid flow path formed in the first flow path space 411 may be formed in a straight line shape.

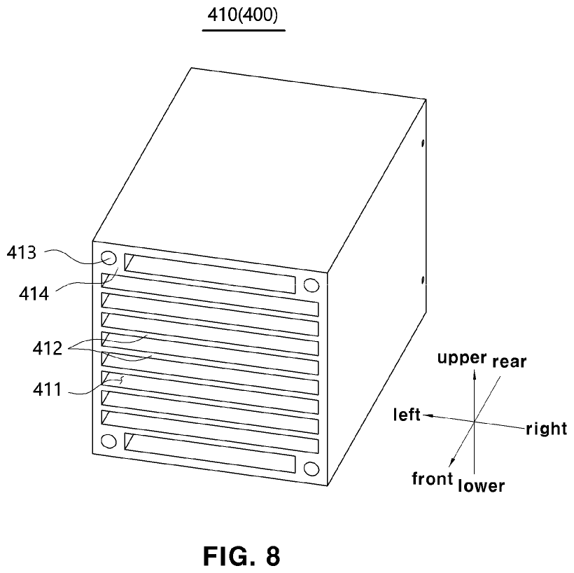

In other words, in the embodiment shown in FIG. 8, the fluid introduced into each partitioned space may flow slightly along the left-right direction, but most of the flow is formed from the front side toward the rear side. Accordingly, the speed of flow formed in each partitioned space may be increased, thereby improving the cooling rate and efficiency.

In addition, fluids flowing in each partitioned space do not mix with each other until they enter the duct module 500. Therefore, turbulence is not formed in each partitioned space, so that fluid may flow more smoothly.

Furthermore, in an embodiment in which the first flow path member 410 is formed of a material having high thermal conductivity, fluid flowing in a pair of spaces adjacent to each other among the partitioned spaces may be heat-exchanged through the first partition member 412. Therefore, while the fluid flows through the first flow path member 410, heat-exchange may be performed between the fluids, thereby improving cooling rate and efficiency.

Meanwhile, the distance between the plurality of spaces partitioned by the plurality of first partition members 412 and the first electrically connected module 310 may be different from each other. Therefore, the amount of heat transmitted to the fluid flowing in each of the plurality of spaces may also be different. When the above situation is maintained, there is a risk that the cooling efficiency of the power conversion module 10 may decrease.

Therefore, the power conversion module 10 according to the embodiment of the present disclosure is configured to allow fluids flowing in each partitioned space to be mixed at least once in the duct module 500.

Accordingly, fluids that flow in each partitioned space and are adjusted to different temperatures by receiving different amounts of heat may be mixed and then flow toward the second flow path member 420. As a result, each of the electrically connected modules 310 and 320 may be cooled more effectively, and detailed descriptions thereof will be given later.

The first fan fastening hole 413 is a portion where the second fan 220 of the blowing member 200 is coupled to the first flow path member 410. The first fan fastening hole 413 is formed at the one end of the first flow path member 410 in the extending direction, that is, at the front end in the illustrated embodiment.

The first fan fastening hole 413 may be recessed at the surface of the end of the first flow path member 410 facing the first cover 110, that is, at the front end in the illustrated embodiment. In an embodiment, the first fan fastening hole 413 may be formed to extend in the extending direction of the first flow path member 410, that is, in the front-rear direction in the illustrated embodiment. In other words, in the above embodiment, the first fan fastening hole 413 may be formed through the first flow path member 410 along the extending direction.

The first fan fastening hole 413 may be disposed at the corners of the one end surface of the first flow path member 410. In addition, a plurality of first fan fastening holes 413 may be formed, and the plurality of first fan fastening holes 413 may be disposed at different positions.

In the illustrated embodiment, four first fan fastening holes 413 are formed. The four first fan fastening holes 413 are respectively disposed at the four corners of the one end of the first flow path member 410 having a square cross-section.

The number and arrangement method of the first fan fastening holes 413 may vary depending on the number and arrangement method of through holes (not reference numerals) formed in the second fan 220.

Any fastening member (not shown) for fastening the second fan 220 may be inserted into and coupled to the first fan fastening hole 413. In an embodiment, the fastening member (not shown) may be provided as a screw member, and may be screwed to the first fan fastening hole 413 after being penetrated through the first cover 110 and the second fan 220.

The first fan fastening hole 413 is surrounded by the first support wall 414.

The first support wall 414 forms a portion of the surface of each end of the first flow path member 410 in the extending direction. The first support wall 414 surrounds the first fan fastening hole 413 radially outside to block the random communication between the first fan fastening hole 413 and the first flow path space 411.

In addition, the first support wall 414 may be in contact with the protrusions 516 and 517 of the duct module 500 to limit the distance at which the first flow path member 410 is inserted into the duct module 500.

The first support wall 414 may be disposed at each end of the first flow path member 410 in the extending direction, that is, at a corner of each side of the front end and the rear end in the illustrated embodiment. In addition, a plurality of first support walls 414 may be formed, and the plurality of first support walls 414 may surround the first fan fastening hole 413 at different locations and may be in contact with protrusions 516 and 517 of the duct module 500.

In the illustrated embodiment, four first support walls 414 are formed on each end face, for a total of eight. Eight first support walls 414 are respectively disposed at the four corners of each end of the first flow path member 410 having a square cross-section.

In an embodiment, four first support walls 414 are provided, and each end in the extending direction may form a portion of a surface of each end in the extending direction of the first flow path member 410. In other words, in the above embodiment, the first support wall 414 may extend by a length that the first flow path member 410 extends.

The first support wall 414 surrounds the first fan fastening hole 413 and may be any shape capable of restricting the insertion length of the first flow path member 410 and the duct module 500 by contacting the protrusions 516 and 517. In the illustrated embodiment, the first support wall 414 extends radially inward from each corner of the end of the first flow path member 410, and has a square cross-section.

The first flow path member 410 communicates with the second flow path member 420 through the duct module 500.

The second flow path member 420 is located adjacent to the other one of the first and second electrically connected modules 310 and 320, and is configured to heat-exchange with the other electrically connected module. That is, the second flow path member 420 is configured to cool the other electrically connected module.

In the illustrated embodiment, the second flow path member 420 is located adjacent to the second electrically connected module 320 located in the front side, and is configured to receive the heat of the second electrically connected module 320.

The second flow path member 420 may extend in the same direction as the extending direction of the housing 100. In the illustrated embodiment, the second flow path member 420 extends in the front-rear direction.

In this case, the extension length of the second flow path member 420 may be longer than the extension length of the first flow path member 410. As described above, this is due to the fact that the heat generated from the second electrically connected module 320 adjacent to the second flow path member 420 generates relatively more heat than the first electrically connected module 310 adjacent to the first flow path member 410. The extension length of the second flow path member 420 may be changed depending on the flow distance of the fluid required for cooling the second electrically connected module 320.

The second flow path member 420 is coupled to the duct module 500. One end of the second flow path member 420 in the extending direction, that is, the front end in the illustrated embodiment, are coupled to the duct module 500.

The second flow path member 420 communicates with the duct module 500. The space formed inside the one end of the second flow path member 420 in the extending direction, that is, the front end in the illustrated embodiment, communicates with the duct space 515 of the duct module 500.

The second flow path member 420 is coupled to the second cover 120. One end of the second flow path member 420 in the extending direction, that is, the rear end in the illustrated embodiment are coupled to the second cover 120.

The second flow path member 420 communicates with the second discharge part 122 formed in the second cover 120. The space formed inside the other end of the second flow path member 420 in the extending direction, that is, the rear end in the illustrated embodiment, communicates with the second discharge part 122.

The second flow path member 420 is disposed to face the first flow path member 410 with the duct module 500 interposed therebetween. That is, in the embodiment shown in FIG. 4, the first flow path member 410, the duct module 500, and the second flow path member 420 are arranged in order from the front side to the rear side.

The second flow path member 420 is located adjacent to the second electrically connected module 320. In an embodiment, the second flow path member 420 may be disposed to be in contact with the components of the second electrically connected module 320, for example, the second PCB 322. In the above embodiment, the second flow path member 420 may function as a heat sink of the second electrically connected module 320.

In the illustrated embodiment, the second flow path member 420 includes a second flow path space 421, a second partition member 422, a second fan fastening hole 423, and a second support wall 424.

The second flow path space 421 is a space formed inside the second flow path member 420. The second flow path space 421 functions as a passage through which the introduced external fluid flows.

The second flow path space 421 extends in the extending direction of the second flow path member 420, that is, in the front-rear direction in the illustrated embodiment. Each end of the second flow path space 421 in the extending direction, that is, the front end and the rear end in the illustrated embodiment, are each open. The front end of the second flow path space 421 communicates with duct space 515. The rear end of the second flow path space 421 communicates with the second discharge part 122 formed in the second cover 120.

The second flow path space 421 may be any shape in which the introduced external fluid may flow. In the illustrated embodiment, the second flow path space 421 has a square cross-section corresponding to the shape of the second flow path member 420 and is formed in a square pillar extending in the front-rear direction.

A second partition member 422 is disposed in the second flow path space 421.

The second partition member 422 divides the second flow path space 421 into a plurality of spaces. The plurality of spaces divided by the second partition member 422 may be physically spaced apart from each other, so that a passage through which the introduced fluid flows may be formed independently.

The second partition member 422 extends in the extending direction of the second flow path member 420, that is, in the front-rear direction in the illustrated embodiment. Each end of the second partition member 422 in the extending direction, that is, the front end and the rear end in the illustrated embodiment, may be disposed on the same plane as each end of the second flow path member 420 in the extending direction. In other words, the second partition member 422 may extend from the second flow path space 421 by the same length as the second flow path member 420.

As the front end of the second partition member 422 is formed adjacent to the duct space 515, the fluid flowing through the duct space 515 may be divided into a plurality of flows by the second partition member 422 and enter the second flow path space 421.

The second partition member 422 may be provided in a plate shape. In the illustrated embodiment, the second partition member 422 is provided in the shape of a square plate having a width by the width (i.e., the length in the left-right direction) of the second flow path space 421 and extending by the length (i.e., the length in the front-rear direction) of the second flow path member 420 and having a thickness in the height (i.e., the length in the up-down direction) direction of the second flow path member 420.

In this case, the cross-section of the second partition member 422 may be formed to be smaller than the cross-section of each space in which the second flow path space 421 is divided.

A plurality of second partition members 422 may be provided. The plurality of second partition members 422 may be spaced apart from each other, and a space in which the second flow path space 421 is partitioned may be disposed between the adjacent second partition members 422.

In the illustrated embodiment, the plurality of second partition members 422 extend in the width direction, that is, the left-right direction, of the second flow path member 420, and are disposed to be spaced apart from each other in the height direction, that is, the up-down direction, of the second flow path member 420. In this case, a plurality of spaces partitioned by the plurality of second partition members 422 extend in the left-right direction.

Alternatively, the plurality of second partition members 422 may be extended in the height direction, that is, the up-down direction, of the second flow path member 420, and may be disposed to be spaced apart from each other in the width direction, that is, left-right direction of the second flow path member 420. In the above embodiment, a plurality of spaces partitioned by the plurality of second partition members 422 may be formed to extend in the up-down direction.

In an embodiment, the plurality of second partition members 422 may extend parallel to each other. In the above embodiment, the amount of fluid flowing in the plurality of partitioned spaces may be uniformly adjusted with each other.

In an embodiment, the structure and arrangement method of the plurality of first partition members 412 may be configured to be the same as the structure and arrangement method of the plurality of second partition members 422.

As the second flow path space 421 is divided into a plurality of spaces having a smaller cross-sectional area by the plurality of second partition members 422, the fluid flow path formed in the second flow path space 421 may be formed in a straight line shape.

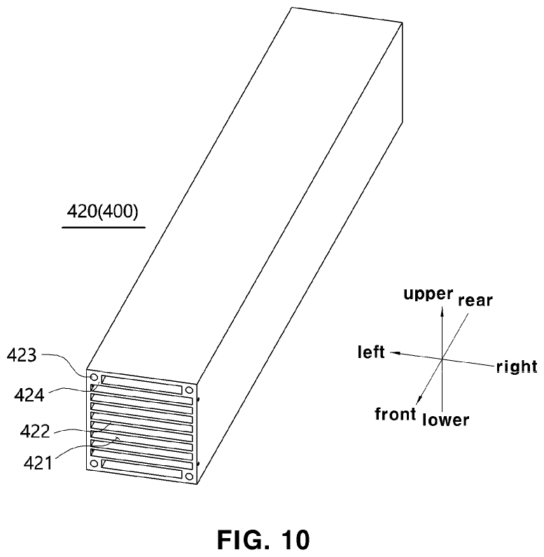

In other words, in the embodiment shown in FIG. 10, the fluid introduced into each partitioned space may flow slightly along the left-right direction, but most of the flow is formed from the front side toward the rear side. Accordingly, the speed of flow formed in each partitioned space may be increased, thereby improving the cooling rate and efficiency.

In addition, the fluids flowing in each partitioned space do not mix with each other until they are discharged to the outside of the housing 100. Therefore, turbulence is not formed in each partitioned space, so that fluid may flow more smoothly.

Furthermore, in an embodiment in which the second flow path member 420 is formed of a material having high thermal conductivity, fluid flowing in a pair of spaces adjacent to each other among the partitioned spaces may be heat-exchanged through the second partition member 422. Therefore, while the fluid flows through the second flow path member 420, heat-exchange may be performed between the fluids, thereby improving cooling rate and efficiency.

The second fan fastening hole 423 is a portion where the blowing member 200 is coupled to the second flow path member 420. The second fan fastening hole 423 is formed at the one end of the second flow path member 420 in the extending direction, that is, at the front end in the illustrated embodiment.

The second fan fastening hole 413 may be recessed at the surface of the end of the second flow path member 420 facing the first cover 110, that is, at the front end in the illustrated embodiment. In an embodiment, the second fan fastening hole 423 may be formed to extend in the extending direction of the second flow path member 420, that is, in the front-rear direction in the illustrated embodiment. In other words, in the above embodiment, the second fan fastening hole 423 may be formed through the second flow path member 420 along the extending direction.

The second fan fastening hole 423 may be disposed at the corners of the one end surface of the second flow path member 420. In addition, a plurality of second fan fastening holes 423 may be formed, and the plurality of second fan fastening holes 423 may be disposed at different positions.

In the illustrated embodiment, four, second fan fastening holes 423 are formed. The four second fan fastening holes 423 are respectively disposed at the four corners of the one end of the second flow path member 420 having a square cross-section.

The number and arrangement method of the second fan fastening holes 423 may vary depending on the number and arrangement method of through holes (not reference numerals) formed in the blowing member 200.

Any fastening member (not shown) for fastening the blowing member 200 may be inserted and coupled to the second fan fastening hole 423. In an embodiment, the fastening member (not shown) may be provided as a screw member, and may be screwed to the second fan fastening hole 423 after being penetrated through the first cover 110 and the blowing member 200.

In the illustrated embodiment, the second flow path member 420 is disposed in the rear side and is not coupled to the separate blowing member 200. Alternatively, when the second flow path member 420 is disposed in the front side, it will be understood that the blowing member 200 may be coupled to the second fan fastening hole 423.

The second fan fastening hole 423 is surrounded by the second support wall 424.

The second support wall 424 forms a portion of the surface of each end of the second flow path member 420 in the extending direction. The second support wall 424 surrounds the second fan fastening hole 423 radially outside to block the random communication between the second fan fastening hole 423 and the second flow path space 421.

In addition, the second support wall 424 may be in contact with the protrusions 516 and 517 of the duct module 500 to limit the distance at which the second flow path member 420 is inserted into the duct module 500.

The second support wall 424 may be disposed at each end of the second flow path member 420 in the extending direction, that is, at a corner of each side of the front end and the rear end in the illustrated embodiment. In addition, a plurality of second support walls 424 may be formed, and the plurality of second support walls 424 may surround the second fan fastening hole 423 at different locations and may be in contact with protrusions 516 and 517 of the duct module 500.

In the illustrated embodiment, four second support walls 424 are formed on each end face, for a total of eight. Eight second support walls 424 are respectively disposed at the four corners of each end of the second flow path member 420 having a square cross-section.

In an embodiment, four second support walls 424 are provided, and each end in the extending direction may form a portion of a surface of each end in the extending direction of the second flow path member 420. In other words, in the above embodiment, the second support wall 424 may extend by a length that the second flow path member 420 extends.

The second support wall 424 surrounds the second fan fastening hole 423 and may be any shape capable of restricting the insertion length of the second flow path member 420 and the duct module 500 by contacting the protrusions 516 and 517. In the illustrated embodiment, the second support wall 424 extends radially inward from each corner of the end of the second flow path member 420, and has a square cross-section.

The first flow path member 410 and the second flow path member 420 may be coupled to the duct module 500, respectively. The first flow path space 411 of the first flow path member 410, the duct space 515, and the second flow path space 421 communicate with each other. In this case, the first flow path member 410 and the second flow path member 420 are surrounded on its outer circumference by the duct module 500 and may be coupled to the duct module 500.

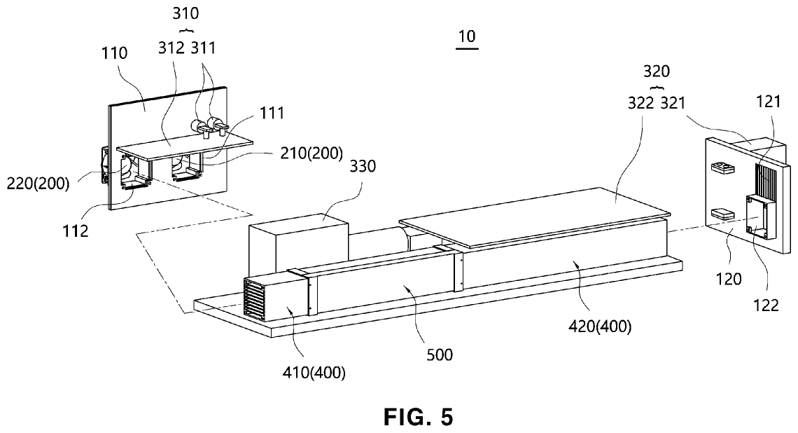

Referring again to FIGS. 5 to 10, the power conversion module 10 according to an embodiment of the present disclosure includes the duct module 500.

The first flow path member 410 and the second flow path member 420 are physically and electrically spaced apart from each other. The reason why the first flow path member 410 and the second flow path member 420 are spaced apart from each other is to ensure an insulation state between the first and second electrically connected modules 310 and 320, which are located adjacent to each other. In other words, the first electrically connected module 310 and the second electrically connected module 320 are electrically connected only by the voltage-transforming module 330.

Therefore, the fluid flowing in the first flow path member 410 to cool the first electrically connected module 310 and the fluid flowing in the second flow path member 420 to cool the second electrically connected module 320 are generally provided as separate flows. Accordingly, the design freedom of the power conversion module 10 is reduced, and there is a limit to miniaturization.

Accordingly, the power conversion module 10 according to the embodiment of the present disclosure includes the duct module 500. The duct module 500 may maintain insulation, that is, an electrical separation between the first flow path member 410 and the second flow path member 420. By using the duct module 500, a sufficient creepage distance between the first flow path member 410 and the second flow path member 420 may be secured.

At the same time, the duct module 500 may be configured to form a flow path extending between the first flow path member 410 and the second flow path member 420 so that a fluid flowing in a single flow path cools the components of the power conversion module 10.

The duct module 500 is coupled to the first flow path member 410 and the second flow path member 420, respectively. The duct module 500 forms a flow path extending between the first flow path member 410 and the second flow path member 420.

The duct module 500 communicates with the first flow path member 410 and the second flow path member 420, respectively. The first flow path member 410 and the second flow path member 420 may be communicated with each other by the duct module 500.

The duct module 500 is located between the first flow path member 410 and the second flow path member 420. In the illustrated embodiment, the first flow path member 410 and the second flow path member 420 are disposed to be spaced apart from each other in the extending direction, that is, the front-rear direction. The duct module 500 is located between the first flow path member 410 and the second flow path member 420 that are spaced apart from each other.

The duct module 500 extends in the same direction as the first flow path member 410 and the second flow path member 420. One end of the duct module 500 in the extending direction is coupled to the first flow path member 410. The other end of the duct module 500 in the extended direction is coupled to the second flow path member 420.

In the illustrated embodiment, the duct module 500 extends in the front-rear direction, and the front end thereof is coupled to the first flow path member 410 and the rear end thereof is coupled to the second flow path member 420.

A space is formed inside the duct module 500. The space communicates with the first flow path space 411 of the first flow path member 410 and the second flow path space 421 of the second flow path member 420, respectively.

The duct module 500 may be formed of a non-conductive material. It is to block any electrical connection between the first flow path member 410 and the second flow path member 420 to which the duct module 500 is coupled.

The duct module 500 may be formed of a material having high thermal conductivity. This is to heat-exchange in the form of conduction with the first flow path member 410 and the second flow path member 420 coupled to the duct module 500. In addition, in the above embodiment, heat staying in the accommodation space 140 may also be transmitted to the duct module 500 to improve cooling efficiency.

The duct module 500 may be any shape capable of forming a fluid flow path for cooling by being coupled to and communicated with the first flow path member 410 and the second flow path member 420, respectively. In the illustrated embodiment, the duct module 500 has a square cross-section and is formed in a square pillar extending in the extending direction, that is, the front-rear direction of the housing 100.

The duct module 500 may extend by a length sufficient to electrically insulate the first electrically connected module 310 (and the first flow path member 410 located adjacent thereto) and the second electrically connected module 320 (and the second flow path member 420 located adjacent thereto). In other words, the extension length of the duct module 500 may be formed to be longer than a sufficient creepage distance for insulating between the first flow path member 410 and the second flow path member 420.

Additionally, the extended length of the duct module 500 may be configured to increase in proportion to the difference in potential between each end of the duct module 500 in the extending direction.

That is, the first flow path member 410 and the second flow path member 420 coupled to each end of the duct module 500 may be maintained at voltages corresponding to the voltages of the power that are electrically connected to the first electrically connected module 310 and the second electrically connected module 320, respectively. Therefore, the difference in voltage between each end of the duct module 500 may be understood as the difference in voltage between the first flow path member 410 and the second flow path member 420.

At this time, the larger the difference in potential between the power electrically connected to the first flow path member 410 and the second flow path member 420, the longer the creepage distance is required. Therefore, it will be understood that the length of the duct module 500 for electrically insulating the first flow path member 410 and the second flow path member 420 also increases depending on the difference in potential between the power electrically connected to the first flow path member 410 and the second flow path member 420.

In other words, the extension length of the duct module 500 may be determined in proportion to the potential difference between the power electrically connected to the first electrically connected module 310 and the power electrically connected to the second electrically connected module 320.

The duct module 500 may surround the first flow path member 410 and the second flow path member 420 from the outside and be coupled to the first flow path member 410 and the second flow path member 420. In the illustrated embodiment, the front end of the duct module 500 surrounds the outer circumference of the rear end of the first flow path member 410. Also, the rear end of the duct module 500 surrounds the front end of the second flow path member 420.

Accordingly, the duct module 500 may be applied without excessive structural changes of the first flow path member 410 and the second flow path member 420.

In the illustrated embodiment, the duct module 500 includes a duct body 510 and a flow path coupling part 520.

The duct body 510 forms a body and an outer shape of the duct module 500. The duct body 510 extends in the extending direction of the duct module 500, that is, in the front-rear direction in the illustrated embodiment.

The duct body 510 may be divided into a plurality of portions. The plurality of portions may each constitute different portions of the duct body 510, and may be combined to form the duct body 510. In the illustrated embodiment, the duct body 510 includes a first portion 510a forming one portion and a second portion 510b forming the other portion.

The first portion 510a forms a portion of the duct body 510, that is, the upper and left sides, in the illustrated embodiment. The second portion 510b forms the other portion of the duct body 510, that is, the lower and right sides in the illustrated embodiment.

The first portion 510a and the second portion 510b may each include at least one bend part. In the above embodiment, a predetermined angle formed by each plate may be orthogonal.

In the illustrated embodiment, the first portion 510a includes a single plate forming an upper portion, a single plate forming a left portion, and a plurality of bent parts in which the plates are engaged at a predetermined angle.

Likewise, the second portion 510b includes a single plate forming a right portion, a single plate forming a lower portion, and a plurality of bent parts in which the plates are engaged at a predetermined angle.

Therefore, when the first portion 510a and the second portion 510b are coupled, the duct body 510 may be closed at the upper side, the lower side, the left side, and the right side. The first portion 510a and the second portion 510b are disposed to surround a space formed inside the duct body 510, that is, the duct space 515.

The first portion 510a and the second portion 510b are formed to extend in the extending direction of the duct body 510, that is, in the front-rear direction in the illustrated embodiment. A flow path coupling part 520 is coupled to each end of the first portion 510a and the second portion 510b in the extending direction.

Specifically, a first outer circumference 521a of a first flow path coupling part 521 is coupled to a front end of the first portion 510a, and a first outer circumference 522a of a second flow path coupling part 522 is coupled to a rear end thereof.

Also, a second outer circumference 522b of a first flow path coupling part 521 is coupled to a front end of the second portion 510b, and a second outer circumference 522b of the second flow path coupling part 522 is coupled to a rear end thereof.

Each end of the first portion 510a and the second portion 510b may be formed to partially surround the first flow path member 410 and the second flow path member 420.

In the illustrated embodiment, the front end of the first portion 510a and the front end of the second portion 510b are disposed to surround the rear end of the first flow path member 410, respectively. Likewise, the rear end of the first portion 510a and the rear end of the second portion 510b are disposed to surround the front end of the second flow path member 420, respectively.

Therefore, the rear end of the first flow path member 410 and the front end of the second flow path member 420 are partially accommodated in the duct space 515 to be described later. This will be described later in detail.

In the illustrated embodiment, the duct body 510 includes a first surface 511, a second surface 512, a third surface 513, a fourth surface 514, the duct space 515, the first protrusion 516, and the second protrusion 517.

The first surface 511, the second surface 512, the third surface 513, and the fourth surface 514 each form one surface of the duct body 510. As described above, the duct body 510 may be divided into a first portion 510a and a second portion 510b, and it may be said that the first surface 511, the second surface 512, the third surface 513, and the fourth surface 514 form part of the first portion 510a and the second portion 510b, respectively.

In the illustrated embodiment, the first surface 511 forms an upper surface of the duct body 510, the second surface 512 forms a lower surface of the duct body 510, the third surface 513 forms a left surface of the duct body 510, and the fourth surface 514 forms a right surface of the duct body 510.

The first to fourth surfaces 511, 512, 513, and 514 extend in the extending direction of the duct body 510, that is, in the front-rear direction in the illustrated embodiment. Each end of the first to fourth surfaces 511, 512, 513, and 514 in the extending direction may partially surround the first flow path member 410 and the second flow path member 420.

In the illustrated embodiment, the front end of the first to fourth surfaces 511, 512, 513, and 514 is disposed to surround the rear end of the first flow path member 410. The rear end of the first to fourth surfaces 511, 512, 513, and 514 is disposed to surround the front end of the second flow path member 420.

The space formed surrounded by the first to fourth surfaces 511, 512, 513, and 514, that is, the space formed inside the duct body 510, may be defined as the duct space 515.

The duct space 515 is a space in which the fluid introduced into the first flow space 411 from the outside flows. The duct space 515 is formed inside the duct body 510, and is a space surrounded by the first to fourth surfaces 511, 512, 513, and 514. In other words, the duct space 515 is a space formed surrounded by the first portion 510a and the second portion 510b.

The duct space 515 is formed through the inside of the duct body 510. In other words, the duct space 515 extends along the duct body 510, and each end in the extending direction is open and communicates with the outside.

In the illustrated embodiment, the front end of the duct space 515 communicates with the first flow path space 411 and the rear end of the duct space 515 communicates with the second flow path space 421. The fluid introduced from the outside into the first flow path space 411 may absorb heat and flow toward the duct space 515. In addition, the fluid introduced into the duct space 515 may be mixed and then flow toward the second flow path space 421 and be discharged to the outside of the housing 100.

The duct space 515 may be any shape in which fluid may flow. In the illustrated embodiment, the duct space 515 is a space in the shape of a square pillar, similar to the duct body 510 in the shape of a square pillar, having a square cross-section and extending in the front-rear direction.

No separate members may be provided inside the duct space 515. In other words, the duct space 515 is formed as a void. Therefore, the fluids introduced into each of the plurality of spaces formed by dividing the first flow path space 411 by the first partition member 412 may be mixed in the duct space 515.

Therefore, branches of fluid flowing in the first flow path space 411 and absorbing different amounts of heat may be mixed in the duct space 515 and heat-exchange with each other. Accordingly, the fluid introduced into the duct space 515 may enter the second flow path space 421 after reaching a state of thermal equilibrium.

Accordingly, the cooling efficiency of the components of the power conversion module 10 may be improved. This will be described later in detail.

The first protrusion 516 limits the coupling length between the duct module 500 and the first flow path member 410. As the first flow path member 410 is inserted into the duct module 500, the first protrusion 516 may contact one end of the first flow path member 410 in the extending direction, that is, the rear end in the illustrated embodiment.

Accordingly, the first flow path member 410 may be accommodated in the duct space 515 only by a predetermined length.

In addition, the first protrusion 516 extends along the duct body 510 to limit the coupling length between the duct module 500 and the second flow path member 420. As the second flow path member 420 is inserted into the duct module 500, the first protrusion 516 may be in contact with one end of the second flow path member 420 in the extending direction, that is, the front end in the illustrated embodiment. Accordingly, the second flow path member 420 may also be accommodated in the duct space 515 only by a predetermined length.

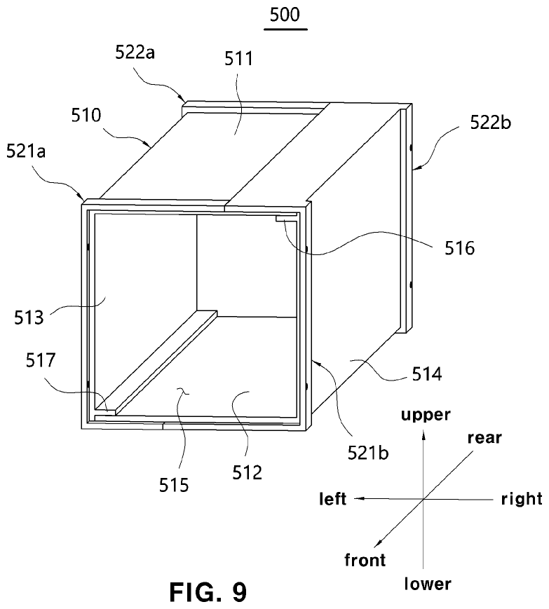

The first protrusion 516 may be formed to protrude toward the duct space 515 from at least one of the first to fourth surfaces 511, 512, 513, and 514. In the embodiment shown in FIG. 9, the first protrusion 516 is formed to protrude from the fourth surface 514 located on the right side toward the duct space 515.

The first protrusion 516 may extend along at least one of the above surfaces coupled thereto. In other words, in the illustrated embodiment, the first protrusion 516 may extend toward the front-rear direction like the fourth surface 514.

Each end of the first protrusion 516 in the extending direction, that is, the front end and the rear end in the illustrated embodiment, may be located on the same plane as the front end and the rear end of either surface, that is, the fourth surface 514 in the illustrated embodiment.

Therefore, one end of the first protrusion 516 in the extending direction, that is, the front end in the illustrated embodiment, may be disposed to be in contact with the first support wall 414 of the first flow path member 410. In addition, the other end of the first protrusion 516 in the extending direction, that is, the rear end in the illustrated embodiment may be disposed to be in contact with the second support wall 424 of the second flow path member 420.

The first protrusion 516 may be disposed adjacent to the other surface that is continuous with the one surface. That is, the first protrusion 516 may be located as close as possible to the other surface surrounding the duct space 515.

Accordingly, the first protrusion 516 does not interfere with the fluid flowing in the duct space 515. In addition, the first protrusion 516 may be spaced apart from the fastening member (not shown) penetrating the flow path coupling part 520.

A second protrusion 517 is located at a different position from the first protrusion 516.

The second protrusion 517 limits the coupling length between the duct module 500 and the first flow path member 410. As the first flow path member 410 is inserted into the duct module 500, the second protrusion 517 may contact one end of the first flow path member 410 in the extending direction, that is, the rear end of the illustrated embodiment.

Accordingly, the first flow path member 410 may be accommodated in the duct space 515 only by a predetermined length.

In addition, the second protrusion 517 extends along the duct body 510 to limit the coupling length between the duct module 500 and the second flow path member 420. As the second flow path member 420 is inserted into the duct module 500, the second protrusion 517 may be in contact with one end of the second flow path member 420 in the direction of extension, that is, the front end in the illustrated embodiment. Accordingly, the second flow path member 420 may also be accommodated in the duct space 515 only by a predetermined length.

The second protrusion 517 may be formed to protrude toward the duct space 515 from at least one of the first to fourth surfaces 511, 512, 513, and 514. In the embodiment shown in FIG. 9, the second protrusion 517 is formed to protrude from the third surface 513 located on the left side toward the duct space 515.

The second protrusion 517 may extend along at least one of the surfaces coupled thereto. In other words, in the illustrated embodiment, the second protrusion 517 may extend toward the front-rear direction like the third surface 513.

Each end of the second protrusion 517 in the direction of extension, that is, the front end and the rear end in the illustrated embodiment, may be located on the same plane as the front end and the rear end of either surface, that is, the third surface 513 in the illustrated embodiment.

Therefore, one end of the second protrusion 517 in the extending direction, that is, the front end in the illustrated embodiment, may be disposed to be in contact with the first support wall 414 of the first flow path member 410. In addition, the other end of the second protrusion 517 in the extending direction, that is, the rear end in the illustrated embodiment, may be disposed to be in contact with the second support wall 424 of the second flow path member 420.

The second protrusion 517 may be disposed adjacent to the other surface that is continuous with the one surface. That is, the second protrusion 517 may be located as close as possible to the other surface surrounding the duct space 515.

Accordingly, the second protrusion 517 does not interfere with the fluid flowing in the duct space 515. In addition, the second protrusion 517 may be spaced apart from the fastening member (not shown) penetrating the flow path coupling part 520.

The first protrusion 516 and the second protrusion 517 may each be formed to have a minimized cross-section. This is to avoid interfering with the flow of fluid flowing in the duct space 515.

The first protrusion 516 and the second protrusion 517 may be disposed at any position that may limit the insertion distance of the first flow path member 410 and the second flow path member 420 at a plurality of points. In the illustrated embodiment, the first protrusion 516 and the second protrusion 517 are spaced apart from each other in the diagonal direction of the duct space 515. Alternatively, the first protrusion 516 and the second protrusion 517 may be disposed on the upper side or the lower side of the duct space 515.

A portion of the outer circumference of the duct body 510 is surrounded by the flow path coupling part 520.

The flow path coupling part 520 couples the duct body 510 and the flow path part 400. The flow path coupling part 520 is coupled to the duct body 510 and the flow path part 400, respectively, and allows the first flow path space 411, the second flow path space 421, and the duct space 515 to communicate with each other, and seal them in the radial direction.

The flow path coupling part 520 partially surrounds the outer circumference of the duct body 510. Specifically, the flow path coupling part 520 surrounds the outer circumference of the duct body 510, and surrounds the outer circumference of the ends, which is a portion surrounding the flow path part 400, in the extending direction, that is, each end in the front-rear direction in the illustrated embodiment.

The flow path coupling part 520 partially surrounds the outer circumference of each end of the first flow path member 410 and the second flow path member 420 coupled to the duct body 510 in the extended direction. In the illustrated embodiment, the first flow path coupling part 521 located at the front side partially surrounds the rear end of the first flow path member 410. In addition, the second flow path coupling part 522 located at the rear side partially surrounds the front end of the second flow path member 420.

Therefore, the first flow path coupling part 521 may be said to extend in the front-rear direction to surround the rear end of the first flow path member 410 and the front end of the duct body 510.

Similarly, the second flow path coupling part 522 may be said to extend in the front-rear direction to surround the rear end of the duct body 510 and the front end of the second flow path member 420.

Therefore, it may be said that the first flow path member 410 and the second flow path member 420 are inserted into and coupled to the space surrounded by the flow path coupling part 520, which communicates with the duct space 515.

Accordingly, even in the embodiment in which the duct module 500 is provided, excessive structural changes of the first flow path member 410 and the second flow path member 420 are not required as described above.

A plurality of flow path coupling parts 520 may be provided. The plurality of flow path coupling parts 520 may be respectively coupled to the duct body 510 and the flow path part 400 at different positions.

In the illustrated embodiment, the flow path coupling part 520 includes a first flow path coupling part 521 located in the front side of the duct body 510 and a second flow path coupling part 522 located in the rear side of the duct body 510.

The first flow path coupling part 521 is located at one end of the duct body 510 in the extending direction, that is, at the front end in the illustrated embodiment. The first flow path coupling part 521 is formed to surround the one end of the duct body 510 from the outside.

The first flow path coupling part 521 is coupled to the one end of the duct body 510 and the one end of the first flow path member 410 inserted into the one end, that is, the rear end in the illustrated embodiment. In an embodiment, the first flow path coupling part 521 may be integrally formed with the duct body 510, or may be separately formed and coupled to the duct body 510 in a form such as welding.

The first flow path coupling part 521 is coupled to the first flow path member 410. The coupling may be formed by a fastening member (not shown) such as a screw member. To this end, a through hole (not reference numerals) through which the fastening member (not shown) passes may be formed in the first flow path coupling part 521.

The first flow path coupling part 521 may extend a predetermined length in the extending direction of the duct body 510, that is, in the front-rear direction in the illustrated embodiment. It is preferable that the first flow path coupling part 521 is long enough to overlap the rear end of the first flow path member 410 accommodated in the duct space 515 in the radial direction.

The first flow path coupling part 521 may be divided into a plurality of portions. The plurality of portions of the first flow path coupling part 521 may form portions on different sides and may be coupled to different surfaces 511, 512, 513, and 514 of the duct body 510.

In the illustrated embodiment, the first flow path coupling part 521 includes a first outer circumference 521a forming part of the left, upper, and lower sides, and a second outer circumference 521b forming part of the upper side, right, and lower sides.

The first outer circumference 521a and the second outer circumference 521b surround the one end of the duct body 510, that is, the front end, respectively. In the illustrated embodiment, the first outer periphery 521a partially surrounds the first surface 511 and the third surface 513. The second outer circumference 521b partially surrounds the second surface 512 and the fourth surface 514.

The second flow path coupling part 522 is located at the other end of the duct body 510 in the extending direction, that is, at the rear end in the illustrated embodiment. The second flow path coupling part 522 is formed to surround the other end of the duct body 510 from the outside.

The second flow path coupling part 522 is coupled to the other end of the duct body 510 and one end of the second flow path member 420 inserted into the other end, that is, the front end in the illustrated embodiment. In one embodiment, the second flow path coupling part 522 may be formed integrally with the duct body 510, or may be formed separately and coupled to the duct body 510 in a form such as welding.

The second flow path coupling part 522 is coupled to the second flow path member 420. The coupling may be formed by a fastening member (not shown) such as a screw member. To this end, a through hole (not reference numerals) through which the fastening member (not shown) passes may be formed in the second flow path coupling part 522.

The second flow path coupling part 522 may extend a predetermined length in the extending direction of the duct body 510, that is, in the front-rear direction in the illustrated embodiment. The second flow path coupling part 522 is preferably formed long enough to overlap the front end of the second flow path member 420 accommodated in the duct space 515 in the radiation direction.

The second flow path coupling part 522 may be divided into a plurality of portions. The plurality of portions of the second flow path coupling part 522 may form portions on different sides and may be coupled to different surfaces 511, 512, 513, and 514 of the duct body 510.

In the illustrated embodiment, the second flow path coupling part 522 includes a first outer circumference 522a forming part of the left, upper, and lower sides, and a second outer circumference 522b forming part of the upper, the right, and lower sides.

The first outer circumference 522a and the second outer circumference 522b surround the other end of the duct body 510, that is, the rear end, respectively. In the illustrated embodiment, the first outer circumference 522a partially surrounds the first surface 511 and the third surface 513. The second outer circumference 522b partially surrounds the second surface 512 and the fourth surface 514.

Although not illustrated, the outer circumferential surface of the flow path part 400 or the outer circumferential surface of the duct module 500 may be formed with a plurality of concave portions and convex portions, and the area thereof may be increased.

In the above embodiment, the outer circumferential surface of the flow path part 400 or the outer circumferential surface of the duct module 500 may be formed to have an area equal to or greater than an area required for electrical insulation. Accordingly, the length of the duct module 500, that is, the separation distance between the first flow path member 410 and the second flow path member 420, may be reduced, and the power conversion module 10 may be further miniaturized.

### 5. Description of the Flow of Fluid in the Power Conversion Module 10 According to an Embodiment of the Present Disclosure

The power conversion module 10 according to an embodiment of the present disclosure may be formed with a fluid flow path for cooling the components through the above-described configuration. Accordingly, each component of the power conversion module 10 may be rapidly and effectively cooled.

At the same time, each component of the power conversion module 10 is electrically sufficiently spaced apart, so that an insulation state may be ensured. Therefore, as the flow path is simplified, the power conversion module 10 is miniaturized and stable operation is possible.

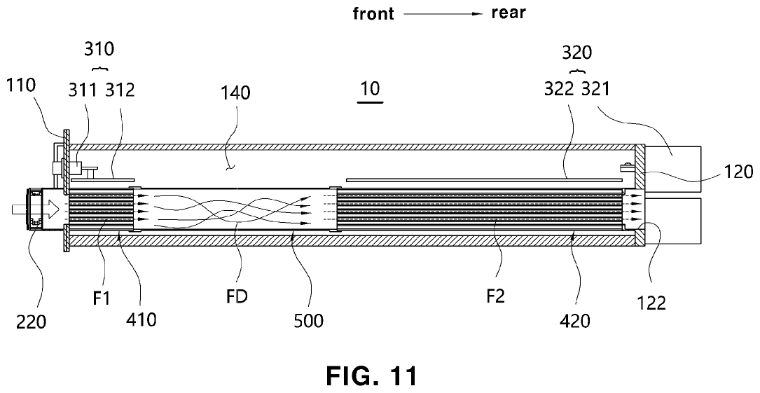

Hereinafter, a flow process of a fluid for cooling each component inside the power conversion module 10 according to an embodiment of the present disclosure will be described in detail with reference to FIG. 11.

As described above, the fluid flowing into the power conversion module 10 may be the fluid staying inside the frame 20. That is, the fluid flowing into the power conversion module 10 is in a state in which dust or suspended substances are removed.

In the illustrated embodiment, a flow path of the fluid flowing in the flow path part 400 and the duct module 500 among the fluids for cooling the components is illustrated. However, it will be understood that a cooling process for the accommodation space 140 itself may be performed simultaneously, as described above.

Specifically, the external fluid may be introduced into the accommodation space 140 through the first inlet part 111 formed in the first cover 110. The introduced fluid may heat-exchange with various components disposed in the accommodation space 140, and after cooling the components, the fluid may be discharged to the outside through the first discharge part 121 formed in the second cover 120.

In the following description, the flow path formed in the flow path part 400 and the duct module 500 will be described in detail. The term “first flow path F1” used in the following description refers to the flow of fluid inside the first flow path member 410, and the term “second flow path F2” refers to the flow of fluid inside the second flow path member 420. Furthermore, the term “duct flow path FD” refers to the flow of fluid inside the duct module 500.

As the second fan 220 disposed in the first cover 110 is operated, external fluid receives the conveying force and is introduced into the first flow space 411 of the first flow path member 410 through the second inlet part 112.

At this time, the first flow path space 411 is divided into a plurality of small spaces by a plurality of first partition members 412. Accordingly, the first flow path F1 is formed as a plurality of branches extending from the plurality of small spaces to divide the introduced external fluid.

As described above, the first flow path member 410 may be formed of a material having high thermal conductivity. Therefore, heat-exchange may be performed between the plurality of branches forming the first flow path F1.

The first flow path F1 extends along the extending direction of the first flow path member 410. That is, the upstream side of the first flow path F1 is located at the front end of the first flow path space 411 that communicates with the second inlet part 112. The downstream side of the first flow path F1 is located at the rear end of the first flow path space 411 that communicates with the duct space 515, and is continuous with the duct flow path FD.

The fluid passing through the first flow path space 411 forms the duct flow path FD.

As described above, the duct space 515 is formed as an empty space without a separate member for partitioning. Therefore, the plurality of branches forming the first flow path F1 are mixed in the duct space 515 to form the duct flow path FD. As the plurality of branches absorbing different amounts of heat are mixed, the fluids forming the duct flow path FD may heat-exchange with each other and be adjusted to the state of thermal equilibrium.

In an embodiment in which the duct module 500 is formed of a material having high thermal conductivity, fluid along the duct flow path FD may undergo additional heat-exchange with the duct module 500. Accordingly, the cooling efficiency of the power conversion module 10 may be further improved.

The duct flow path FD extends along the extending direction of the duct body 510. In other words, the upstream side of the duct flow path FD is located in the front side of the duct space 515 communicating with the first flow path space 411. The downstream side of the duct flow path FD is located at the front end of the second flow path space 421, which communicates with the second flow path space 421, and is continuous with the second flow path F2.

The fluid passing through the duct space 515 forms a second flow path F2.

As described above, the second flow path space 421 is also divided into a plurality of small spaces by a plurality of second partition members 422. Therefore, the second flow path F2 is also formed as a plurality of branches extending from the plurality of small spaces to divide the fluid to form the duct flow path FD.

As described above, the second flow path member 420 may also be formed of a material having high thermal conductivity. Therefore, heat-exchange may also be performed between the plurality of branches forming the second flow path F2.

The second flow path F2 extends along the extending direction of the second flow path member 420. That is, the upstream side of the second flow path F2 is located at the front end of the second flow path space 421 that communicates with the duct space 515. The downstream side of the second flow path F2 is located at the rear end of the second flow path space 421 that communicates with the second discharge part 122 of the second cover 120.

In the embodiment illustrated in FIG. 11, the second flow path F2 is formed longer than the first flow path F1. This is due to the fact that the second flow path member 420 formed with the second flow path F2 is located adjacent to the second electrically connected module 320 that generates relatively more heat.

The fluid forming the second flow path F2 is discharged to the outside of the second flow path member 420 and the housing 100 through the second discharge part 122. The discharged fluid is cooled inside the frame 20 and then introduced into the power conversion module 10 again, and may be utilized to cool the components of the power conversion module 10.

Although exemplary embodiments of the present disclosure have been described, the idea of the present disclosure is not limited to the embodiments set forth herein. Those of ordinary skill in the art who understand the idea of the present disclosure may easily propose other embodiments through supplement, change, removal, addition. etc. of elements within the same idea, but the embodiments will be also within the scope of the present disclosure.

| | |
|---|---|
| 1: power supply device | 10: power conversion module |
| 20: frame | 30: door |
| 100: housing | 110: first cover |
| 111: first inlet part | 112: second inlet part |
| 120: second cover | 121: first discharge part |
| 122: second discharge part | 130: handle member |
| 140: accommodation space | 200: blowing member |
| 210: first fan | 220: second fan |
| 300: electrically connected part | 310: first electrically connected |
| module | |
| 311: first terminal | 312: first PCB |
| 320: second electrically connected | 321: second terminal |
| module | |
| 322: second PCB | 330: voltage-transforming module |
| 400: flow path part | 410: first flow path member |
| 411: first flow path space | 412: first partition member |
| 413: first fan fastening hole | 414: first support wall |
| 420: second flow path member | 421: second flow path space |
| 422: second partition member | 423: second fan fastening hole |
| 424: second support wall | 500: duct module |
| 510: duct body | 510a: first portion |
| 510b: second portion | 511: first surface |
| 512: second surface | 513: third surface |
| 514: fourth surface | 515: duct space |
| 516: first protrusion | 517: second protrusion |
| 520: flow path coupling part | 521: first flow path coupling part |
| 521a: first outer circumference | 521b: second outer circumference |
| 522: second first flow path coupling | 522a: first outer circumference |
| part | |
| 522b: second outer circumference | F1: first flow path |
| F2: second flow path | FD: duct flow path |

1. A duct module, comprising:
a duct body formed to extend in one direction and communicating with a flow path member respectively; and
a flow path coupling part coupling the duct body to the flow path member respectively and,
wherein the duct body comprises:
a duct space that is formed inside the duct body, extends in the one direction, and is formed to be open at each end in the extending direction to communicate with the flow path member; and
at least one surface surrounding the duct space in an outer circumferential direction.

2. The duct module of claim 1, wherein the duct body comprises:
a protrusion formed to extend toward the duct space on the at least one surface, and in contact with an end surface in the extending direction of the flow path member.

3. The duct module of claim 2, wherein the duct body comprises:
a pair of surfaces continuous with each other at a predetermined angle to partially surround the duct space, and
wherein the protrusion protrudes from any one surface of the pair of surfaces and is disposed adjacent to the other surface of the pair of surfaces.

4. The duct module of claim 1, wherein the duct body comprises:
a first surface that surrounds one side of the duct space;
a second surface that is disposed to face the first surface with the duct space interposed therebetween, and surrounds another side of the duct space;
a third surface that is continuous with the first surface and the second surface, respectively, and surrounds still another side of the duct space; and
a fourth surface that is continuous with the first surface and the second surface, respectively, and is disposed to face the third surface with the duct space interposed therebetween, and surrounds the other side of the duct space,
wherein the first surface, the second surface, the third surface, and the fourth surface extend in the one direction.

5. The duct module of claim 4, wherein the duct body comprises:
a first protrusion protruding on any one surface of the first surface to the fourth surface toward the duct space; and
a second protrusion protruding on the other surface of the first surface to the fourth surface toward the duct space,
wherein the first protrusion and the second protrusion contact with a surface of one end facing the duct body among the both ends in the extending direction of the flow path member.

6. The duct module of claim 5, wherein the first protrusion and the second protrusion are disposed to be spaced apart from each other in a diagonal direction of the duct space.

7. The duct module of claim 5, wherein the first protrusion is disposed adjacent to one surface continuous with the one surface at a predetermined angle, and
the second protrusion is disposed adjacent to the other surface continuous with the other surface at a predetermined angle.

8. The duct module of claim 1, wherein the flow path member extends along the one direction, and
the flow path coupling part extends in the one direction to surround:
an outer circumference of one end facing the flow path member among both ends in the extending direction of the duct body; and
an outer circumference of one end facing the duct body among both ends in the extending direction of the flow path member.

9. The duct module of claim 1, wherein the duct body and the flow path coupling part are formed of an electric insulating material.

10. A duct module of claim 1, wherein one end of the direction in which the duct body extends is coupled to a first flow path member of the outside to which power of a voltage of a predetermined magnitude is electrically connected, the other end of the direction in which the duct body extends is coupled to a second flow path member of the outside to which power of a voltage of a different magnitude from the predetermined magnitude is electrically connected, and
the distance between the one end and the other end is proportional to the difference in magnitude between the voltage of the predetermined magnitude electrically connected to the first flow path member and the voltage of the different magnitude electrically connected to the second flow path member.

11. The power conversion module, comprising:
a housing having an accommodating space therein and communicating with the outside;
an electrically connected part that is accommodated in the accommodating space, is electrically connected to an external power source and an external load, respectively, receives power from the external power source, and transforms the received power and transmits the transformed power to the external load;
a flow path part that is accommodated in the accommodating space, is located adjacent to the electrically connected part, and in which a flow path space communicating with the outside is formed, and through which a fluid heat-exchanging with the electrically connected part flows; and
a duct module that is accommodated in the accommodating space, and in which a duct space communicating with the flow path space is formed, and that forms a passage with the flow path part, wherein the fluid flows through the passage, and
wherein the flow path part and the duct module are formed to extend in one direction, and the fluid flows along the one direction inside the flow path part and inside the duct module.

12. The power conversion module of claim 11, wherein the flow path part comprises:
a plurality of partition members located in the flow path space and formed in a plate shape extended along the one direction, and
wherein the flow path space is divided into a plurality of spaces by the plurality of the partition members, and the fluid introduced is branched and flows in each of the plurality of spaces.

13. The power conversion module of claim 12, wherein the introduced fluid flows in the flow path space and the duct space in order, and the branched fluid flowing in the plurality of spaces is mixed in the duct space.

14. The power conversion module of claim 12, wherein the duct module comprises:
a duct body with the duct space formed therein; and
a flow path coupling part surrounding an outer circumference of the duct body and extending toward the flow path part from an end of the duct body in the extending direction.

15. The power conversion module of claim 14, wherein the duct module comprises:
a protrusion formed to extend toward the duct space on a surface surrounding the duct space, and
wherein the flow path part is disposed so that a surface of one end in the extending direction thereof is in contact with the protrusion.

16. The power conversion module of claim 15, wherein the flow path coupling part surrounds each end of the duct body and the flow path part facing each other from the outside.
